(19) United States
(12) Patent Application Publication
(10) Pub. No.: US 2026/0002254 A1
(43) Pub. Date: Jan. 1, 2026

(54) DEPOSITION APPARATUS, METHOD OF MANUFACTURING DISPLAY PANEL USING THE DEPOSITION APPARATUS, AND ELECTRONIC DEVICE MANUFACTURED BY USING THE DEPOSITION APPARATUS

(71) Applicant: Samsung Display Co., LTD., Yongin-si (KR)

(72) Inventors: Sung Jin KIM, Yongin-si (KR); Jun Ha PARK, Yongin-si (KR); Yun Seok CHANG, Yongin-si (KR); Dong Hyun HAN, Yongin-si (KR)

(21) Appl. No.: 19/074,711

(22) Filed: Mar. 10, 2025

(30) Foreign Application Priority Data
Jun. 27, 2024 (KR) 10-2024-0084568

(51) Int. Cl. C23C 16/04; C23C 16/458; H01L 21/683; H10K 71/16

(52) U.S. Cl. CPC C23C 16/042; C23C 16/4583; H01L 21/6831; H10K 71/166

(57) ABSTRACT

Provided are a deposition apparatus, a method of manufacturing a display panel using the deposition apparatus, and an electronic device manufactured by using the deposition apparatus. The deposition apparatus includes a deposition source configured to provide a deposition material onto a substrate, a substrate chuck configured to support the substrate such that the substrate faces the deposition source, a mask chuck disposed between the deposition source and the substrate chuck and configured to support a deposition mask such that the deposition mask faces the substrate, a substrate chuck driver configured to move the substrate chuck such that the substrate is positioned on the deposition mask, and a chuck pressurizing portion configured to apply pressure to a central portion of the substrate chuck such that the substrate chuck is convexly deformed toward the deposition mask.

This application claims priority to Korean Patent Application No. 10-2024-0084568, filed on Jun. 27, 2024, and all the benefits accruing therefrom under 35 U.S.C. § 119, the content of which in its entirety is herein incorporated by reference.

### BACKGROUND

### 1. Technical Field

The present disclosure relates to a deposition apparatus, a method of manufacturing a display panel using the deposition apparatus, and an electronic device manufactured by using the deposition apparatus.

### 2. Description of the Related Art

Wearable devices that have the form of glasses or a helmet and form a focus in front of and at a distance close to a user's eyes have been developed. For example, the wearable devices may be a head mounted display (HMD) device or augmented reality (AR) glasses. Such wearable devices may provide an augmented reality (hereinafter referred to as “AR”) screen or a virtual reality (hereinafter referred to as “VR”) screen to a user.

A wearable device such as, for example, an HMD device or AR glasses may be implemented with display specifications of about 3,000 pixels per inch (PPI) or more in order for the user to use the wearable device for a long time without dizziness. To this end, organic light emitting diode on silicon (OLEDoS) technology, which may be used in a small organic light emitting display device having a high resolution, has emerged. OLEDOS technology is a technology that disposes organic light emitting diodes (OLEDs) on a semiconductor wafer on which complementary metal oxide semiconductor (CMOS) elements are disposed.

In order to manufacture a display panel having a high resolution of about 3000 PPI or more, a deposition mask having a high resolution and a deposition apparatus using the deposition mask may be used. For example, the deposition mask may be manufactured by forming a membrane having a plurality of pixel openings on a substrate such as, for example, a silicon wafer and partially etching the substrate to form cell openings exposing the pixel openings. The deposition apparatus may include a mask stage supporting the deposition mask, a substrate chuck supporting a substrate such that the substrate is positioned on the deposition mask, a deposition source providing a deposition material onto the substrate through the pixel openings of the deposition mask, and the like.

However, when a warpage phenomenon occurs due to residual stress of the membrane, a difference in coefficient of thermal expansion between the substrate and the membrane, and the like, in a manufacturing process of the deposition mask or a phenomenon in which the membrane sags downward due to its own weight occurs during a period in which a deposition process is performed, a gap between the substrate and the deposition mask may increase, and parallelism between the substrate and the deposition mask may deteriorate.

### SUMMARY

Aspects and features of embodiments of the present disclosure provide a deposition apparatus capable of keeping a gap between a substrate and a deposition mask constant and improving parallelism between the substrate and the deposition mask, a method of manufacturing a display panel using the deposition apparatus, and an electronic device manufactured by using the deposition apparatus.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, a deposition apparatus includes a deposition source configured to provide a deposition material onto a substrate, a substrate chuck configured to support the substrate such that the substrate faces the deposition source, a mask chuck disposed between the deposition source and the substrate chuck and configured to support a deposition mask such that the deposition mask faces the substrate, a substrate chuck driver configured to move the substrate chuck such that the substrate is positioned on the deposition mask, and a chuck pressurizing portion configured to apply pressure to a central portion of the substrate chuck such that the substrate chuck is convexly deformed toward the deposition mask.

The chuck pressurizing portion may be configured to apply the pressure the central portion of the substrate chuck such that the substrate chuck is deformed within an elastic limit.

The central portion of the substrate chuck may convexly protrude toward the deposition mask by a displacement amount of about 0.5 μm to about 2 μm based on the pressure applied by the chuck pressurizing portion.

The substrate chuck driver may include a hexapod actuator configured to provide motion of six degrees of freedom.

The substrate chuck driver may further include a substrate stage on which the hexapod actuator is mounted, and the hexapod actuator may include a first platform connected to the substrate chuck, a second platform mounted on the substrate stage, and six sub-actuators disposed between the first platform and the second platform.

The substrate chuck driver may further include a second actuator configured to move the substrate stage in a central axis direction of the hexapod actuator.

The chuck pressurizing portion may include a piezo actuator disposed between the first platform and the substrate chuck and configured to apply the pressure to the central portion of the substrate chuck.

The substrate chuck may be an electrostatic chuck configured to hold the substrate using electrostatic force.

The electrostatic chuck may include a first electrostatic electrode configured to provide a first electrostatic force associated with holding a central portion of the substrate, and a second electrostatic electrode configured to provide a second electrostatic force associated with holding an edge portion of the substrate.

The deposition apparatus may further include a power supply unit configured to apply a first electrostatic voltage and a second electrostatic voltage to the first electrostatic electrode and the second electrostatic electrode, respectively. In such case, the power supply unit may be configured to apply the first electrostatic voltage to the first electrostatic electrode and apply the second electrostatic voltage to the second electrostatic electrode, wherein the second electrostatic voltage may be applied after the first electrostatic voltage.

The deposition apparatus may further include a mask chuck driver configured to move the mask chuck associated with adjusting a position of the deposition mask.

The mask chuck driver may include a piezo actuator configured to move the mask chuck in a direction parallel to the deposition mask and rotate the mask chuck based on a central axis of the mask chuck, and a mask stage configured to support the piezo actuator.

The deposition apparatus may further include a plurality of gap sensors configured to measure a gap between the substrate chuck and the mask chuck. In such case, the substrate chuck driver may be configured to adjust a gradient of the substrate chuck based on measured values provided by the plurality of gap sensors in association with adjusting parallelism between the substrate and the deposition mask.

The deposition apparatus may further include a plurality of first gap sensors configured to measure a gap between the substrate chuck and the mask chuck. In such case, the substrate chuck driver may be configured to move the substrate chuck such that the substrate is spaced apart from the deposition mask by a first gap, and then primarily adjust a gradient of the substrate chuck based on measured values provided by the plurality of first gap sensors in association with primarily adjusting parallelism between the substrate and the deposition mask.

The deposition apparatus may further include a plurality of second gap sensors configured to measure the gap between the substrate chuck and the mask chuck and having a higher resolution than the plurality of first gap sensors. In such case, the substrate chuck driver may be configured to move the substrate chuck such that the substrate is spaced apart from the deposition mask by a second gap smaller than the first gap, and then secondarily adjust the gradient of the substrate chuck based on measured values provided by the plurality of second gap sensors in association with secondarily adjusting the parallelism between the substrate and the deposition mask.

The deposition apparatus may further include an illumination portion configured to provide light, wherein the substrate and the deposition mask may be configured to transmit the light, and a camera configured to detect the light transmitted through the substrate and the deposition mask.

The substrate chuck driver may be configured to move the substrate chuck in association with aligning the substrate and the deposition mask with each other based on image information acquired by the camera.

The illumination portion may include an infrared lamp mounted in the substrate chuck, and the mask chuck may have a through hole configured to pass the light transmitted through the substrate and the deposition mask.

The deposition apparatus may further include an illumination portion configured to provide light onto the substrate through the deposition mask, and a camera configured to detect light reflected from the substrate and transmitted through the deposition mask.

The deposition mask may include a mask frame and a membrane disposed on the mask frame. The membrane may have a mask alignment key, and the mask frame may have a key opening exposing the mask alignment key.

The deposition apparatus may further include a plurality of lift fingers configured to load the substrate onto the substrate chuck and load the deposition mask onto the mask chuck.

A plurality of slots may be provided at side portions of the substrate chuck and enable raising and lowering movement of the plurality of lift fingers.

According to one or more embodiments of the present disclosure, a method of manufacturing a display panel includes loading a substrate onto a substrate chuck, loading a deposition mask onto a mask chuck which is disposed facing the substrate chuck, moving the substrate chuck such that the substrate is positioned on the deposition mask, applying pressure to a central portion of the substrate chuck such that the substrate chuck is convexly deformed toward the deposition mask, and forming a deposition material layer on the substrate by providing a deposition material onto the substrate through the deposition mask.

The pressure may be applied to the central portion of the substrate chuck such that the substrate chuck is deformed within an elastic limit.

The central portion of the substrate chuck may convexly protrude toward the deposition mask by a displacement amount of about 0.5 μm to about 2 μm, based on the pressure applied to the central portion of the substrate chuck.

The method may further include generating, by the substrate chuck, a first electrostatic force associated with holding a central portion of the substrate, and generating, by the substrate chuck, a second electrostatic force associated with holding an edge portion of the substrate, wherein generating the second electrostatic force is after generating the first electrostatic force.

The method may further include measuring gaps between the substrate chuck and the mask chuck using a plurality of gap sensors, and adjusting parallelism between the substrate and the deposition mask based on the measured gaps.

The method may further include moving the substrate chuck such that the substrate is spaced apart from the deposition mask by a first gap, primarily measuring gaps between the substrate chuck and the mask chuck using a plurality of first gap sensors, and primarily adjusting parallelism between the substrate and the deposition mask based on the primarily measured gaps.

The method may further include moving the substrate chuck such that the substrate is spaced apart from the deposition mask by a second gap smaller than the first gap, secondarily measuring gaps between the substrate chuck and the mask chuck using a plurality of second gap sensors having a higher resolution than the plurality of first gap sensors, and secondarily adjusting the parallelism between the substrate and the deposition mask based on the secondarily measured gaps.

The method may further include providing light which transmits through the substrate and the deposition mask, and acquiring image information by detecting the light transmitted through the substrate and the deposition mask, and aligning the substrate and the deposition mask with each other based on the image information.

The method may further include providing light onto the substrate through the deposition mask, acquiring image information by detecting light reflected from the substrate and transmitted through the deposition mask, and aligning the substrate and the deposition mask with each other based on the image information.

According to one or more embodiments of the present disclosure, an electronic device may include a display panel including a substrate and a plurality of light-emitting layers formed on the substrate by a deposition apparatus. In such case, the deposition apparatus may include a deposition source configured to provide a deposition material onto the substrate, a substrate chuck configured to support the substrate such that the substrate faces the deposition source, a mask chuck disposed between the deposition source and the substrate chuck and configured to support a deposition mask such that the deposition mask faces the substrate, a substrate chuck driver configured to move the substrate chuck such that the substrate is positioned on the deposition mask, and a chuck pressurizing portion configured to apply pressure to a central portion of the substrate chuck such that the substrate chuck is convexly deformed toward the deposition mask.

According to embodiments of the present disclosure as described herein, a central portion of a substrate chuck may be convexly deformed toward a deposition mask by a chuck pressurizing portion, and accordingly, a central portion of a substrate may be in close contact with the deposition mask. As a result, a gap between the substrate and the deposition mask may become uniform, and parallelism between the substrate and the deposition mask may be improved.

Other features and embodiments may be apparent from the following detailed description and the drawings.

### BRIEF DESCRIPTION OF THE DRAWINGS

The above and other aspects and features of the present disclosure will become more apparent by describing in detail example embodiments thereof with reference to the attached drawings, in which:

FIG. 1 is an exploded perspective view illustrating a display device;

FIG. 2 is a block diagram for explaining the display device illustrated in FIG. 1;

FIG. 3 is an equivalent circuit diagram for explaining an example of a first sub-pixel illustrated in FIG. 2;

FIG. 4 is a schematic plan view illustrating an example of the display panel illustrated in FIG. 1;

FIG. 5 is a schematic plan view illustrating an example of the display area illustrated in FIG. 4;

FIG. 6 is a schematic plan view illustrating another example of the display area illustrated in FIG. 4;

FIG. 7 is a cross-sectional view illustrating an example of the display panel taken along line I-I′ of FIG. 5;

FIG. 8 is a schematic perspective view illustrating an example of a head mounted display;

FIG. 9 is a schematic exploded perspective view illustrating the head mounted display illustrated in FIG. 8;

FIG. 10 is a schematic perspective view illustrating another example of a head mounted display;

FIG. 11 is a schematic view illustrating a deposition apparatus according to an embodiment of the present disclosure;

FIG. 12 is a schematic cross-sectional view illustrating a substrate chuck illustrated in FIG. 11;

FIG. 13 is a schematic plan view illustrating the substrate chuck and lift fingers illustrated in FIG. 11;

FIG. 14 is a schematic cross-sectional view illustrating a method of unloading a substrate from the substrate chuck illustrated in FIG. 11;

FIG. 15 is a schematic bottom view illustrating a substrate illustrated in FIG. 11;

FIG. 16 is a schematic plan view illustrating a deposition mask illustrated in FIG. 11;

FIG. 17 is a schematic enlarged plan view illustrating mask cell regions illustrated in FIG. 16;

FIG. 18 is a schematic cross-sectional view taken along line II-II′ illustrated in FIG. 17;

FIG. 19 is a schematic plan view illustrating a mask chuck illustrated in FIG. 11;

FIG. 20 is a schematic cross-sectional view illustrating the mask chuck illustrated in FIG. 11;

FIG. 21 is a schematic view illustrating a substrate chuck driver and a mask chuck driver illustrated in FIG. 11;

FIGS. 22 and 23 are schematic views illustrating a chuck pressurizing portion, the substrate, and the deposition mask illustrated in FIG. 21;

FIG. 24 is a schematic plan view illustrating gap sensors disposed on the substrate chuck;

FIG. 25 is a schematic cross-sectional view taken along line III-III′ illustrated in FIG. 24;

FIG. 26 is a schematic enlarged cross-sectional view illustrating an illumination portion and a camera illustrated in FIG. 11;

FIG. 27 is a schematic enlarged cross-sectional view illustrating another example of the illumination portion and the camera illustrated in FIG. 26;

FIG. 28 is a schematic enlarged cross-sectional view illustrating the deposition mask illustrated in FIG. 27;

FIG. 29 is a flowchart illustrating a method of manufacturing a display panel according to another embodiment of the present disclosure;

FIG. 30 is a flowchart illustrating S120 illustrated in FIG. 29; and

FIG. 31 is a flowchart illustrating another example of S120 illustrated in FIG. 29.

### DETAILED DESCRIPTION

The invention will now be described more fully hereinafter with reference to the accompanying drawings, in which various embodiments of the present disclosure are illustrated. Aspects supported by the present disclosure may, however, be embodied in different forms and should not be construed as limited to the embodiments set forth herein. Rather, the example embodiments are provided such that this disclosure will be thorough and complete, and will filly convey the scope of example aspects of the present disclosure to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” and the like may be used herein to describe various elements, these elements should not be limited by these terms. These terms are used to distinguish one element from another element. For instance, a first element discussed below could be termed a second element without departing from the teachings of the invention. Similarly, the second element could also be termed the first element.

The terminology used herein is for the purpose of describing particular example embodiments and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as, for example, “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Features of each of various embodiments of the disclosure may be partially or entirely combined with each other and may technically variously interwork with each other, and respective embodiments may be implemented independently of each other or may be implemented together in association with each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel. The term “substantially reflects light” means reflects approximately or actually an entirety of the light.

The term “adjacent” herein may refer to elements which are relatively close to each other (e.g., within a threshold distance) or elements which are in contact with each other. For example, for an emission area (e.g., first emission area EA1) described as adjacent to another emission area (e.g., second emission area EA2), another emission area is not present between the adjacent emission areas.

It is to be understood that characteristics described herein with respect to relative terms such as, for example, “high,” “low,” and the like refer to the characteristics satisfying (e.g., being greater than, less than, or the like) a threshold associated with the characteristics.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

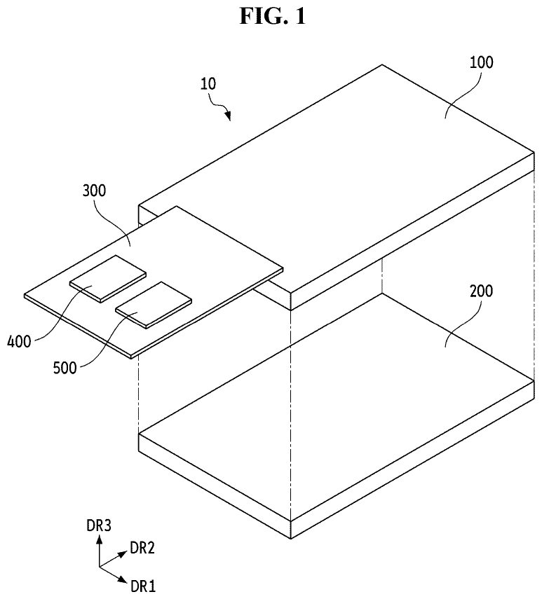

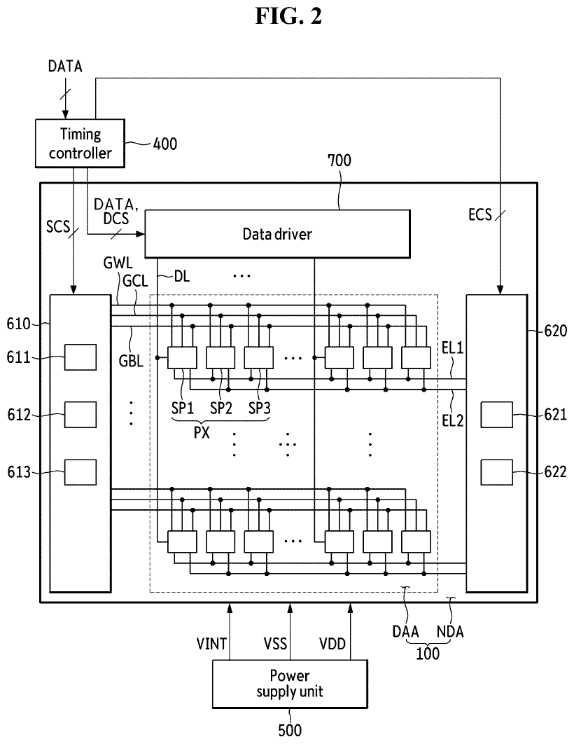

FIG. 1 is an exploded perspective view illustrating a display device. FIG. 2 is a block diagram for explaining the display device illustrated in FIG. 1.

Referring to FIGS. 1 and 2, a display device 10 may be a device displaying a moving image or a still image. The display device 10 may be applied to portable electronic devices such as, for example, a mobile phone, a smartphone, a tablet personal computer (PC), a mobile communication terminal, an electronic organizer, an electronic book, a portable multimedia player (PMP), a navigation system, an ultra-mobile PC (UMPC) and the like. For example, the display device 10 may be applied as a display unit of electronic devices such as, for example, a television, a laptop, a monitor, a billboard, an Internet-of-Things (IoT) device, and the like. Alternatively, the display device 10 may be applied to electronic devices such as, for example, a smart watch, a watch phone, a head mounted display (HMD) for implementing virtual reality and augmented reality, and the like.

The display device 10 may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but embodiments of the present disclosure are not limited thereto.

The display panel 100 may include a plurality of pixels PX, a plurality of scan lines SL, a plurality of emission control lines EL, a plurality of data lines DL, a scan driver 610, an emission driver 620, and a data driver 700. As illustrated in FIG. 2, the display panel 100 may be divided into a display area DAA displaying an image and a non-display area NDA not displaying an image.

The plurality of pixels PX may be disposed in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

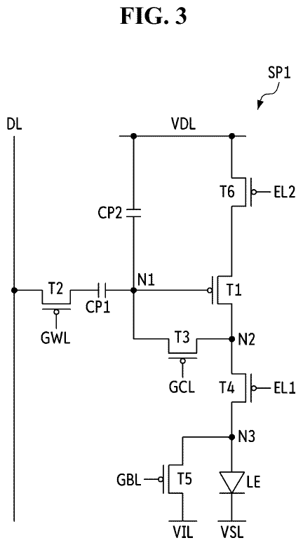

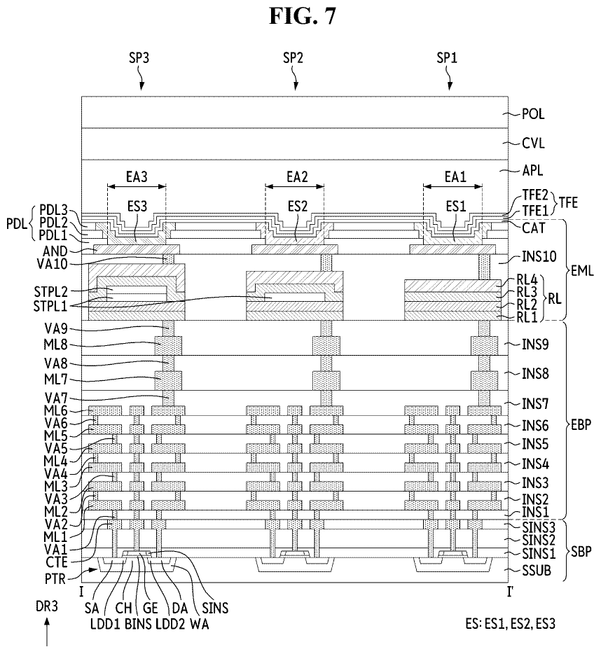

The plurality of pixels PX may include a plurality of sub-pixels SP1, SP2, and SP3. The plurality of sub-pixels SP1, SP2, and SP3 may include a plurality of pixel transistors (see FIG. 3). The plurality of pixel transistors may be formed by a semiconductor process, and may be disposed on a semiconductor substrate SSUB (see FIG. 7). For example, the plurality of pixel transistors of the data driver 700 may be formed through a complementary metal oxide semiconductor (CMOS) process, but embodiments of the present disclosure are not limited thereto.

Each of the plurality of sub-pixels SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

The scan driver 610, the emission driver 620, and the data driver 700 may be disposed in the non-display area NDA.

The scan driver 610 may include a plurality of scan transistors, and the emission driver 620 may include a plurality of light-emitting transistors. The plurality of scan transistors and the plurality of light-emitting transistors may be formed on the semiconductor substrate SSUB (see FIG. 7) through a semiconductor process. For example, the plurality of scan transistors and the plurality of light-emitting transistors may be formed through a CMOS process, but the embodiment of the present specification is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed through a semiconductor process, and formed on the semiconductor substrate SSUB (see FIG. 7). For example, the plurality of data transistors may be formed through a CMOS process, but embodiments of the present disclosure are not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, for example, on the rear surface of the display panel 100. The heat dissipation layer 200 serves to dissipate heat generated from the display panel 100. The heat dissipation layer 200 may include a metal layer having high thermal conductivity, such as, for example, graphite, silver (Ag), copper (Cu), or aluminum (Al).

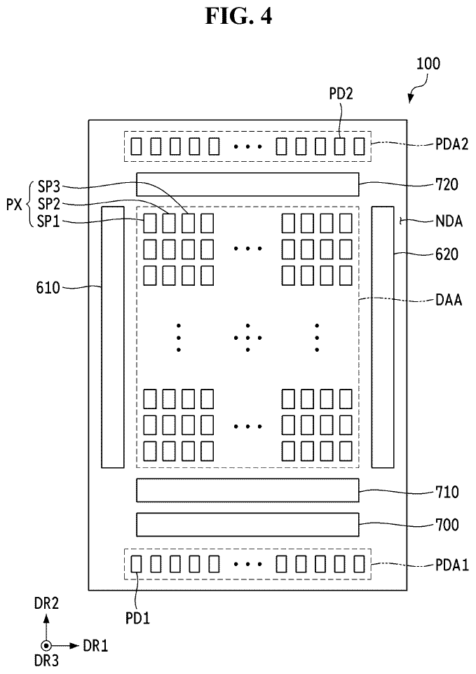

The circuit board 300 may be electrically connected to a plurality of first pads PD1 (see FIG. 4) of a first pad portion PDA1 (see FIG. 4) of the display panel 100 by using a conductive adhesive member such as, for example, an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

As another example, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed through a semiconductor process, and formed on the semiconductor substrate SSUB (see FIG. 7). For example, the plurality of timing transistors and the plurality of power transistors may be formed through a CMOS process, but embodiments of the present disclosure are not limited thereto. Each of the timing control circuit 400 and the power supply circuit 500 may be disposed between the data driver 700 and the first pad portion PDA1 (see FIG. 4).

FIG. 3 is an equivalent circuit diagram for explaining an example of a first sub-pixel illustrated in FIG. 2.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 may include a plurality of transistors T1 to T6, a light-emitting element LE, a first capacitor CP1, and a second capacitor CP2.

The light-emitting element LE emits light in response to a driving current flowing through the channel of the first transistor T1. The emission amount of the light-emitting element LE may be proportional to the driving current. The light-emitting element LE may be disposed between a fourth transistor T4 and the first driving voltage line VSL. The first electrode of the light-emitting element LE may be connected to the drain electrode of the fourth transistor T4, and the second electrode of the light-emitting element LE may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but embodiments of the present disclosure are not limited thereto. For example, the light-emitting element LE may be an inorganic light-emitting element including a first electrode, a second electrode, and an inorganic semiconductor disposed between the first electrode and the second electrode, in which case the light-emitting element LE may be a micro light-emitting diode.

The first transistor T1 may be a driving transistor that controls a source-drain current (hereinafter referred to as “driving current”) flowing between the source electrode and the drain electrode of the first transistor T1 according to a voltage applied to the gate electrode of the first transistor T1. The first transistor T1 may include a gate electrode connected to a first node N1, a source electrode connected to the drain electrode of a sixth transistor T6, and a drain electrode connected to a second node N2.

A second transistor T2 may be disposed between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be disposed between the first node N1 and the drain electrode of the second transistor T2. The first capacitor CP1 may include one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but embodiments of the present disclosure are not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that illustrated in FIG. 3. For example, the number of transistors and the number of capacitors of the first sub-pixel SP1 are not limited to those illustrated in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 will be omitted in the present disclosure.

FIG. 4 is a schematic plan view illustrating an example of the display panel illustrated in FIG. 1.

Referring to FIG. 4, the display area DAA of the display panel 100 may include the plurality of pixels PX arranged in a matrix form. The non-display area NDA of the display panel 100 may include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. That is, as illustrated in FIG. 4, the scan driver 610 may be disposed on the left side of the display area DAA, and the emission driver 620 may be disposed on the right side of the display area DAA. However, embodiments of the present disclosure are not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2. The first pad portion PDA1 may be disposed outside the data driver 700 in the second direction DR2. That is, as illustrated in FIG. 4, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or probe pins during an inspection process, or may be connected to a circuit board for inspection. The circuit board for inspection may be a printed circuit board formed of a rigid material or a flexible printed circuit board formed of a flexible material.

The second pad portion PDA2 may be disposed on the fourth side of the display area DAA. For example, the second pad portion PDA2 may be disposed on the other side of the display area DAA in the second direction DR2. The second pad portion PDA2 may be disposed outside the second distribution circuit 720 in the second direction DR2. That is, as illustrated in FIG. 4, the second pad portion PDA2 may be disposed closer to the edge of the display panel 100 than the second distribution circuit 720.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, as illustrated in FIG. 4, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. That is, as illustrated in FIG. 4, the second distribution circuit 720 may be disposed on the upper side of the display area DAA.

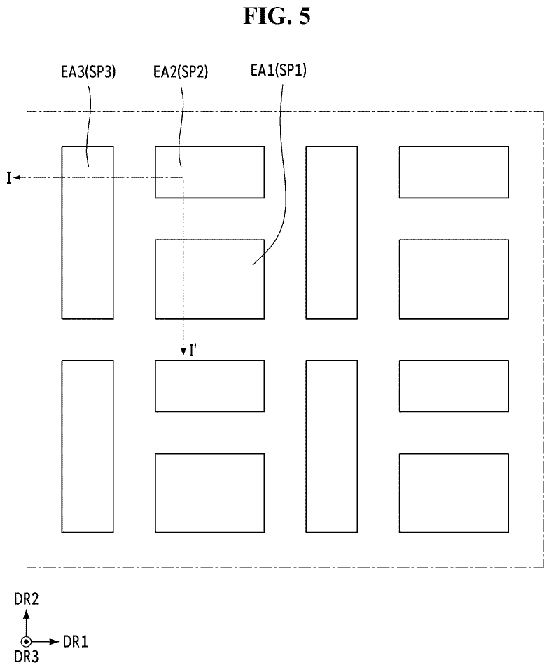

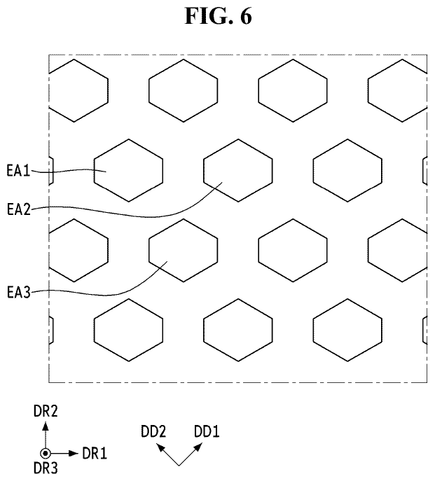

FIG. 5 is a schematic plan view illustrating an example of the display area illustrated in FIG. 4. FIG. 6 is a schematic plan view illustrating another example of the display area illustrated in FIG. 4.

Referring to FIG. 5, each of the plurality of pixels PX may include a first sub-pixel SP1, a second sub-pixel SP2, and a third sub-pixel SP3. The first to third sub-pixels SP1, SP2, and SP3 may include emission areas EA1, EA2, and EA3, respectively. For example, the first sub-pixel SP1 may include the first emission area EA1, the second sub-pixel SP2 may include the second emission area EA2, and the third sub-pixel SP3 may include the third emission area EA3.

Each of the first emission area EA1, the second emission area EA2, and the third emission area EA3 may be an area defined by a pixel defining film PDL (see FIG. 7). For example, each of the first emission area EA1, the second emission area EA2, and the third emission area EA3 may be an area defined by a first pixel defining film PDL1 (see FIG. 7).

The length of the third emission area EA3 in the first direction DR1 may be less than the length of the first emission area EA1 in the first direction DR1, and the length of the second emission area EA2 in the first direction DR1. The length of the first emission area EA1 in the first direction DR1 and the length of the second emission area EA2 in the first direction DR1 may be substantially the same.

The length of the third emission area EA3 in the second direction DR2 may be greater than the length of the first emission area EA1 in the second direction DR2, and the length of the second emission area EA2 in the second direction DR2. The length of the first emission area EA1 in the second direction DR2 may be greater than the length of the second emission area EA2 in the second direction DR2.

In each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. Further, the second emission area EA2 and the third emission area EA3 may be adjacent to each other in the first direction DR1. The area of the first emission area EA1, the area of the second emission area EA2, and the area of the third emission area EA3 may be different from each other.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

As another example, as illustrated in FIG. 6, the first emission area EA1, the second emission area EA2, and the third emission area EA3 may be disposed in a hexagonal structure having a hexagonal shape in plan view. In this case, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2.

Although it is illustrated in FIGS. 5 and 6 that each of the plurality of pixels PX includes the three emission areas EA1, EA2, and EA3, embodiments of the present disclosure are not limited thereto. That is, each of the plurality of pixels PX may include four emission areas. Further, each of the emission areas EA1, EA2, and EA3 may have a polygonal, circular, elliptical, or atypical shape in plan view, unlike those illustrated in FIGS. 5 and 6.

The arrangement of the emission areas EA1, EA2, and EA3 of the plurality of pixels PX is not limited to that illustrated in FIGS. 5 and 6. For example, the emission areas of the plurality of pixels PX may be disposed in a stripe structure in which the emission areas are arranged in the first direction DR1, a PenTile® structure in which the emission areas are arranged in a diamond shape, or the like.

FIG. 7 is a cross-sectional view illustrating an example of the display panel taken along line I-I′ of FIG. 5.

Referring to FIG. 7, the display panel 100 may include a semiconductor backplane SBP, a light-emitting element backplane EBP, a display element layer EML, an encapsulation layer TFE, an adhesive layer APL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed at top surface portions of the semiconductor substrate SSUB. The plurality of well regions WA may be regions doped with a second type impurity. The second type impurity may be different from the aforementioned first type impurity. In an example in which the first type impurity is a p-type impurity, the second type impurity may be an n-type impurity. Alternatively, when the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode of the pixel transistor PTR, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having an impurity concentration lower than an impurity concentration of the source region SA. The second low-concentration impurity region LDD2 may be a region having an impurity concentration lower than an impurity concentration of the drain region DA. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, such that punch-through and hot carrier phenomena that might be caused by a short channel may be reduced or prevented.

A first semiconductor insulating film SINS1 may be disposed on the semiconductor substrate SSUB. The first semiconductor insulating film SINS1 may be formed of silicon carbonitride (SiCN) or a silicon oxide (SiOx)-based inorganic film, but embodiments of the present disclosure are not limited thereto.

A second semiconductor insulating film SINS2 may be disposed on the first semiconductor insulating film SINS1. The second semiconductor insulating film SINS2 may be formed of a silicon oxide (SiOx)-based inorganic film, but the embodiment of the present specification is not limited thereto.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through contact plugs penetrating the first semiconductor insulating film SINS1 and the second semiconductor insulating film INS2.

The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on side surfaces of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but the embodiment of the present specification is not limited thereto.

The semiconductor substrate SSUB may be replaced with a glass substrate or a polymer resin substrate such as, for example, polyimide. In this case, thin film transistors may be disposed on the glass substrate or the polymer resin substrate. The glass substrate may be a rigid substrate that does not bend, and the polymer resin substrate may be a flexible substrate that can be bent or curved.

The light-emitting element backplane EBP may include a plurality of conductive layers ML1 to ML8, a plurality of vias VA1 to VA9, and a plurality of insulating films INS1 to INS9. The plurality of insulating films INS1 to INS9 may be used for electrical insulation between the plurality of conductive layers ML1 to ML8.

The first to eighth conductive layers ML1 to ML8 are connected to the plurality of contact terminals CTE exposed from the semiconductor backplane SBP, and serve to implement the circuit of the first sub-pixel SP1 illustrated in FIG. 3. For example, the first to sixth transistors T1 to T6 are formed in the semiconductor backplane SBP, and the connection of the first to sixth transistors T1 to T6 and the first and second capacitors C1 and C2 may be implemented by the first to eighth conductive layers ML1 to ML8. In some aspects, the connection between the drain region corresponding to the drain electrode of the fourth transistor T4, the source region corresponding to the source electrode of the fifth transistor T5, and a first electrode AND of the light-emitting element LE (see FIG. 3) may also be implemented by the first to eighth conductive layers ML1 to ML8.

The first insulating film INS1 may be disposed on the semiconductor backplane SBP. Each of the first vias VA1 may penetrate the first insulating film INS1 and be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and be connected to the first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and be connected to the second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and be connected to the third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and be connected to the fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and be connected to the fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and be connected to the sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and be connected to the seventh conductive layer ML7. Each of the eighth conductive layers ML8 may be disposed on the eighth insulating film INS8 and may be connected to the eighth via VA8.

The first to eighth conductive layers ML1 to ML8 may be formed of substantially the same material. The first to eighth conductive layers ML1 to ML8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be formed of substantially the same material. The first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. First to eighth insulating films INS1 to INS8 may be formed of a silicon oxide (SiOx)-based inorganic film, but the embodiment of the present specification is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9,000 Å. The thickness of each of the seventh via VA7 and the eighth via VA8 may be approximately 6,000 Å.

A ninth insulating film INS9 may be disposed on the eighth insulating film INS8 and the eighth conductive layer ML8. The ninth insulating film INS9 may be formed of a silicon oxide (SiOx)-based inorganic film, but the embodiment of the present specification is not limited thereto.

Each of the ninth vias VA9 may penetrate the ninth insulating film INS9 and be connected to the eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be approximately 16,500 Å.

The display element layer EML may be disposed on the light-emitting element backplane EBP. The display element layer EML may include a reflective electrode layer RL, a tenth insulating film INS10, a tenth via VA10, light-emitting elements LE, and a pixel defining film PDL. Each of the light-emitting elements LE may include a first electrode AND, a light-emitting stack ES, and a second electrode CAT.

The reflective electrode layer RL may be disposed on the ninth insulating film INS9. The reflective electrode layer RL may include at least one reflective electrode RL1, RL2, RL3, and RL4, a first step layer STPL1, and a second step layer STPL2. For example, the reflective electrode layer RL may include first to fourth reflective electrodes RL1, RL2, RL3, and RL4 as illustrated in FIG. 7.

Each of the first reflective electrodes RL1 may be disposed on the ninth insulating film INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

The first step layer STPL1 may be disposed on the second reflective electrode RL2 in the second sub-pixel SP2 and the third sub-pixel SP3. The first step layer STPL1 may not be disposed on the second reflective electrode RL2 in the first sub-pixel SP1.

The second step layer STPL2 may be disposed on the first step layer STPL1 in the third sub-pixel SP3. The second step layer STPL2 may not be disposed on the second reflective electrode RL2 in the first sub-pixel SP1. In some aspects, the second step layer STPL2 may not be disposed on the first step layer STPL1 in the second sub-pixel SP2.

The thickness of the first step layer STPL1 may be set in consideration of the wavelength of the light of the second color and a distance from the light-emitting stack ES of the second sub-pixel SP2 to the fourth reflective electrode RL4 to advantageously reflect the light of the second color emitted from the light-emitting stack ES. The thickness of the second step layer STPL2 may be set in consideration of the wavelength of the light of the third color and a distance from the light-emitting stack ES of the third sub-pixel SP3 to the fourth reflective electrode RL4 to advantageously reflect the light of the third color emitted from the light-emitting stack ES.

The first step layer STPL1 and the second step layer STPL2 may be formed of silicon carbonitride (SiCN) or a silicon oxide (SiOx)-based inorganic film, but the embodiment of the present specification is not limited thereto.

In the first sub-pixel SP1, the third reflective electrode RL3 may be disposed on the second reflective electrode RL2. In the second sub-pixel SP2, the third reflective electrode RL3 may be disposed on the first step layer STPL1 and the second reflective electrode RL2. In the third sub-pixel SP3, the third reflective electrode RL3 may be disposed on the second step layer STPL2 and the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

At least one of the first reflective electrode RL1, the second reflective electrode RL2, and the third reflective electrode RL3 may be omitted.

Each of the fourth reflective electrodes RL4 may be disposed on the third reflective electrode RL3. The fourth reflective electrodes RL4 may be a layer that reflects light from the light-emitting stack ES. The fourth reflective electrodes RL4 may include metal having high reflectivity to advantageously reflect the light. In some aspects, since the fourth reflective electrode RL4 is an electrode that substantially reflects light from the light-emitting elements LE, the thickness of the fourth reflective electrode RL4 may be greater than the thickness of each of the first reflective electrode RL1, the second reflective electrode RL2, and the third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include aluminum (Al) or titanium (Ti).

The tenth insulating film INS10 may be disposed on the ninth insulating film INS9 and the fourth reflective electrodes RL4. The tenth insulating film INS10 may be an optical auxiliary layer through which light reflected by the reflective electrode layer RL passes, among light emitted from the light-emitting elements LE. The tenth insulating film INS10 may be formed of a silicon oxide (SiOx)-based inorganic film, but embodiments of the present disclosure are not limited thereto.

Each of the tenth vias VA10 may penetrate the tenth insulating film VA10 and be connected to the reflective electrode layer RL. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

The thicknesses of the tenth vias VA10 may be different in the first sub-pixel SP1, the second sub-pixel SP2, and the third sub-pixel SP3 associated with adjusting a resonance distance of light emitted from the light-emitting elements LE in at least one of the first sub-pixel SP1, the second sub-pixel SP2, or the third sub-pixel SP3. For example, the thickness of the tenth via VA10 in the third sub-pixel SP3 may be less than the thickness of the tenth via VA10 in each of the first sub-pixel SP1 and the second sub-pixel SP2. Further, the thickness of the tenth via VA10 in the second sub-pixel SP2 may be smaller than the thickness of the tenth via VA10 in the first sub-pixel SP1. That is, the distance between the light-emitting stack ES and the reflective electrode layer RL may be different in the first sub-pixel SP1, the second sub-pixel SP2, and the third sub-pixel SP3.

In summary, associated with adjusting the distance between the light-emitting stack ES and the reflective electrode layer RL according to the main wavelength of light emitted from the first sub-pixel SP1, the second sub-pixel SP2, and the third sub-pixel SP3, the presence or absence of the first and second step layers STPL1 and STPL2 and the thickness of each of the first and second step layers STPL1 and STPL2 in the first sub-pixel SP1, the second sub-pixel SP2, and the third sub-pixel SP3 may be set.

The first electrode AND of each of the light-emitting elements LE may be disposed on the tenth insulating film INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light-emitting elements LE may be titanium nitride (TiN).

The pixel defining film PDL may be disposed on the tenth insulating film INS10 and a part of the first electrode AND of each of the light-emitting elements LE. The pixel defining film PDL may cover the edge of the first electrode AND of each of the light-emitting elements LE. The pixel defining film PDL may serve to partition the first emission areas EA1, the second emission areas EA2, and the third emission areas EA3. That is, the pixel defining film PDL may have openings that partially expose the first electrode AND of each of the light-emitting elements LE.

The first emission area EA1 may be defined as an area in which the first electrode AND, the light-emitting stack ES, and the second electrode CAT are sequentially stacked in the first sub-pixel SP1 to emit light. The second emission area EA2 may be defined as an area in which the first electrode AND, the light-emitting stack ES, and the second electrode CAT are sequentially stacked in the second sub-pixel SP2 to emit light. The third emission area EA3 may be defined as an area in which the first electrode AND, the light-emitting stack ES, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the tenth insulating film INS10 and the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOx)-based inorganic film, but the embodiment of the present specification is not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 are formed as one pixel defining film, the height of the one pixel defining film increases, such that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the widths of the openings of the first pixel defining film PDL1 may be less than the widths of the openings of the second pixel defining film PDL2, and the widths of the openings of the second pixel defining film PDL2 may be less than the widths of the openings of the third pixel defining film PDL3.

The light-emitting stack ES may include a first light-emitting stack ES1 disposed in the first emission area EA1, a second light-emitting stack ES2 disposed in the second emission area EA2, and a third light-emitting stack ES3 disposed in the third emission area EA3. Although not illustrated in detail, the first light-emitting stack ES1 may include a hole injecting layer HIL, a hole transporting layer HTL, a first light-emitting layer EML1, an electron transporting layer ETL, and an electron injecting layer EIL, the second light-emitting stack ES2 may include the hole injecting layer HIL, the hole transporting layer HTL, a second light-emitting layer EML2, the electron transporting layer ETL, and the electron injecting layer EIL, and the third light-emitting stack ES3 may include the hole injecting layer HIL, the hole transporting layer HTL, a third light-emitting layer EML3, the electron transporting layer ETL, and the electron injecting layer EIL.

For example, the hole injecting layer HIL may be disposed on the first electrodes AND exposed by the openings of the pixel defining film PDL, the inner surfaces of the openings of the pixel defining film PDL, and the top surface of the pixel defining film PDL. The hole transporting layer HTL may be disposed on the hole injecting layer HIL.

The first to third light-emitting layers EML1, EML2, and EML3 may be respectively disposed in the openings of the pixel defining film PDL on the hole transporting layer HTL. The first light-emitting layer EML1 may be disposed in the opening of the pixel defining film PDL in the first emission area EA1, and may emit light of a first color, for example, red light. The second light-emitting layer EML2 may be disposed in the opening of the pixel defining film PDL in the second emission area EA2, and may emit light of a second color, for example, green light. The third light-emitting layer EML3 may be disposed in the opening of the pixel defining film PDL in the third emission area EA3, and may emit light of a third color, for example, blue light.

The electron transporting layer ETL may be disposed on the first to third light-emitting layers EML1, EML2, and EML3 and the hole transporting layer HTL, and the electron injecting layer EIL may be disposed on the electron transporting layer ETL.

In another example, although not illustrated, a plurality of trenches (not illustrated) may be disposed between the first to third emission areas EA1, EA2, and EA3. The trenches may have a ring shape respectively surrounding the first to third emission areas EA1, EA2, and EA3, and may be formed to penetrate the pixel defining film PDL. The hole injecting layer HIL and the hole transporting layer HTL formed on the first electrodes AND of the first to third emission areas EA1, EA2, and EA3 may be disconnected from each other by the trenches.

In another example, the first to third light-emitting stacks ES1, ES2, and ES3 may be respectively disposed in the openings of the pixel defining film PDL, and may not be disposed on the pixel defining film PDL. In this case, the first to third light-emitting stacks ES1, ES2, and ES3 may be disconnected from each other by the pixel defining film PDL.

The second electrode CAT may be disposed on the first to third light-emitting stacks ES1, ES2, and ES3. The second electrode CAT may be formed of a transparent conductive material (TCO) such as, for example, ITO or IZO that can transmit light or a semi-transmissive conductive material such as, for example, magnesium (Mg), silver (Ag), or an alloy of Mg and Ag. In an example in which the second electrode CAT is formed of a semi-transmissive conductive material, the light emission efficiency may be improved in each of the first to third sub-pixels SP1, SP2, and SP3 due to a micro-cavity effect. The encapsulation layer TFE may be disposed on the display element layer EML.

The encapsulation layer TFE may include at least one inorganic film TFE1 and TFE2 to reduce or prevent oxygen or moisture from permeating into the display element layer EML. For example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNx), silicon oxynitride (SiON), and silicon oxide (SiOx) are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOx) or aluminum oxide (AlOx), but the embodiment of the present specification is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

The adhesive layer APL may be a layer for increasing the interfacial adhesion between the encapsulation layer TFE and the cover layer CVL. The adhesive layer APL may be an organic film such as, for example, acrylic resin, epoxy resin, phenolic resin, polyamide resin, or polyimide resin.

The cover layer CVL may be disposed on the adhesive layer APL. The cover layer CVL may be a glass substrate or a polymer resin. In an example in which the cover layer CVL is a glass substrate, the cover layer CVL may be attached onto the adhesive layer APL and may serve as an encapsulation substrate. In an example in which the cover layer CVL is a polymer resin, the cover layer CVL may be directly applied onto the adhesive layer APL.

The polarizing plate POL may be disposed on the cover layer CVL. The polarizing plate POL may be a structure for reducing or preventing visibility degradation caused by reflection of external light. The polarizing plate POL may include a linear polarizing plate and a phase retardation film. For example, the phase retardation film may be a N/4 plate (quarter-wave plate), but embodiments of the present disclosure are not limited thereto.

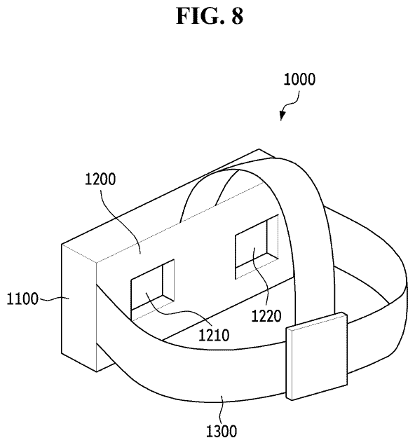

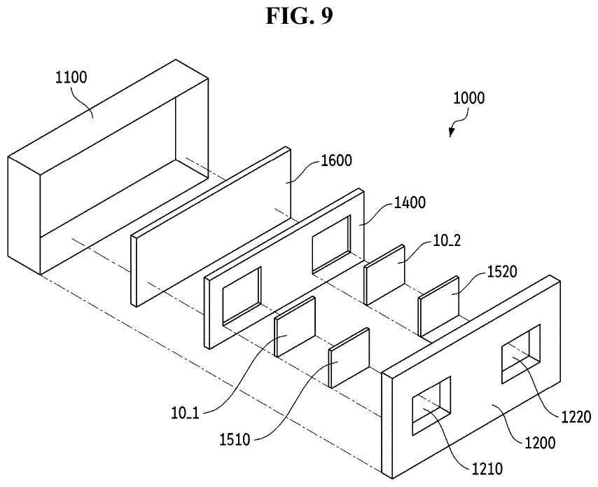

FIG. 8 is a schematic perspective view illustrating a head mounted display. FIG. 9 is a schematic exploded perspective view illustrating an example of the head mounted display illustrated in FIG. 8.

Referring to FIGS. 8 and 9, a head mounted display 1000 according to an embodiment may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 may provide an image to the user's left eye, and the second display device 10_2 provides an image to the user's right eye. Since each of the first display device 10_1 and the second display device 10_2 is substantially the same as the display device 10 described in conjunction with FIGS. 1 and 2, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first and second display devices 10_1 and 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed such that the housing cover 1200 covers an open surface of the display device housing 1100. The housing cover 1200 may include the first eyepiece 1210 at which the user's left eye is located and the second eyepiece 1220 at which the user's right eye is located. FIGS. 8 and 9 illustrate that the first eyepiece 1210 and the second eyepiece 1220 are disposed separately, but embodiments of the present disclosure are not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

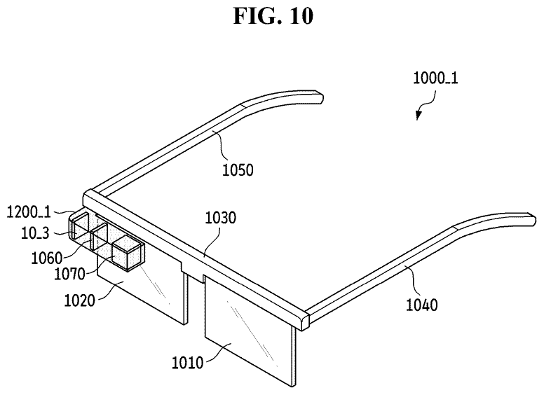

The head mounted band 1300 serves to secure the display device housing 1100 to the user's head such that the first eyepiece 1210 and the second eyepiece 1220 of the housing cover 1200 remain located on the user's left and right eyes, respectively. In an example in which the display device housing 1100 is implemented to be lightweight and compact, the head mounted display 1000 may be provided in the form of glasses as illustrated in FIG. 10.

In some aspects, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a schematic perspective view illustrating another example of a head mounted display.

Referring to FIG. 10, a head mounted display 1000_1 may be an eyeglasses-type display device in which a display device housing 1200_1 is implemented in a lightweight and compact manner. The head mounted display 1000_1 may include a display device 10_3, a left eye lens 1010, a right eye lens 1020, a support frame 1030, temples 1040 and 1050, an optical member 1060, an optical path conversion member 1070, and the display device housing 1200_1.

The display device housing 1200_1 may include the display device 10_3, the optical member 1060, and the optical path conversion member 1070. The image displayed on the display device 10_3 may be magnified by the optical member 1060, and may be provided to the user's right eye through the right eye lens 1020 after the optical path of the image is changed by the optical path changing member 1070. As a result, the user may view an augmented reality image, through the right eye, in which a virtual image displayed on the display device 10_3 and a real image seen through the right eye lens 1020 are combined.

FIG. 10 illustrates that the display device housing 1200_1 is disposed at the right end of the support frame 1030, but embodiments of the present disclosure are not limited thereto. For example, the display device housing 1200_1 may be disposed at the left end of the support frame 1030, and in this case, the image of the display device 10_3 may be provided to the user's left eye. As another example, the display device housing 1200_1 may be disposed at both the left and right ends of the support frame 1030, and in this case, the user may view the image displayed on the display device 10_3 through both the left and right eyes.

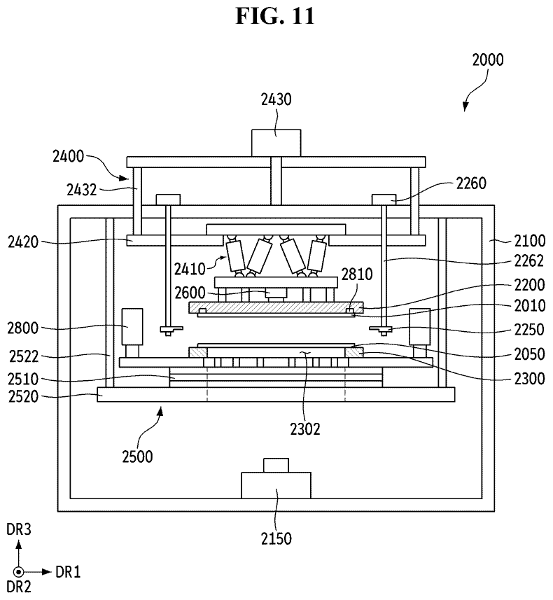

FIG. 11 is a schematic view illustrating a deposition apparatus according to an embodiment of the present disclosure.

Referring to FIG. 11, a deposition apparatus 2000 according to an embodiment of the present disclosure may be used to form light emitting material layers on a substrate 2010 in order to manufacture the display panel 100. For example, as illustrated in FIG. 7, the semiconductor backplane SBP and the light emitting element backplane EBP may be disposed on the substrate 2010, and the reflective electrode layer RL and the insulating film INS10 may be disposed on the light emitting element backplane EBP. The electrode patterns, for example, the anode electrodes AND, may be disposed on the insulating film INS10, and the anode electrodes AND may be electrically connected to the reflective electrode layer RL through the vias VA10. For example, the deposition apparatus 2000 according to an embodiment of the present disclosure may be used to form the light emitting stacks ES1, ES2, and ES3 on the anode electrodes AND.

According to an embodiment of the present disclosure, the deposition apparatus 2000 may include a deposition source 2150 providing a deposition material onto the substrate 2010, a substrate chuck 2200 supporting the substrate 2010 such that the substrate 2010 faces the deposition source 2150, and a mask chuck 2300 disposed between the deposition source 2150 and the substrate chuck 2200 and supporting a deposition mask 2050 such that the deposition mask 2050 faces the substrate 2010. The deposition source 2150, the substrate chuck 2200, and the mask chuck 2300 may be disposed in a process chamber 2100 (or an evaporation chamber).

The process chamber 2100 may include an internal space, and a deposition process for forming a deposition material layer on the substrate 2010 may be performed in the internal space of the process chamber 2100. The process chamber 2100 may be connected to a vacuum pump (not illustrated), and a vacuum atmosphere may be created in the internal space of the process chamber 2100 by the vacuum pump. An opening (not illustrated) for the entrance and exit of the substrate 2010 and the deposition mask 2050 may be provided in one sidewall of the process chamber 2100, and may be opened and closed by a gate valve (not illustrated).

The deposition source 2150 may be disposed inside the process chamber 2100, and a deposition material may be accommodated inside the deposition source 2150. The deposition source 2150 may evaporate a deposition material such as, for example, an organic material, an inorganic material, or a conductive material toward the substrate 2010, and the evaporated deposition material may be deposited on the substrate 2010 through the deposition mask 2050. For example, the deposition source 2150 may evaporate an organic material for forming the light emitting material layers on the substrate 2010, and may include a heater (not illustrated) for evaporating the organic material. The evaporated organic material may be deposited on the electrode patterns on the substrate 2010 through the deposition mask 2050. As illustrated in FIG. 11, the deposition source 2150 is disposed on a central portion of a bottom surface of the process chamber 2100, but may also be configured to be movable in a horizontal direction by a separate driver (not illustrated).

The substrate chuck 2200 may be disposed above the deposition source 2150, and may support the substrate 2010 such that the substrate 2010 faces the deposition source 2150. For example, the substrate chuck 2200 may be an electrostatic chuck holding a rear surface of the substrate 2010 using electrostatic force. Specifically, the electrode patterns, that is, the anode electrodes AND, may be disposed on a front surface of the substrate 2010, and the substrate chuck 2200 may hold the rear surface of the substrate 2010 such that the front surface of the substrate 2010 faces downward, that is, faces the deposition source 2150.

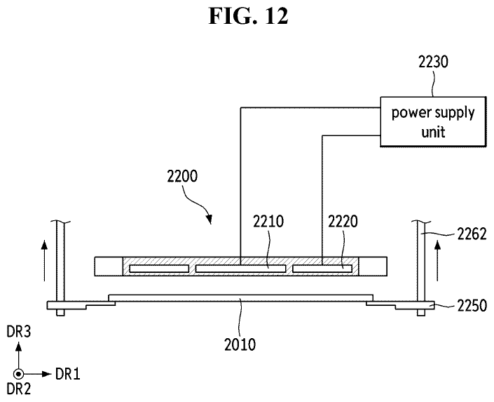

FIG. 12 is a schematic cross-sectional view illustrating a substrate chuck illustrated in FIG. 11.

Referring to FIGS. 11 and 12, the substrate chuck 2200 may hold the rear surface of the substrate 2010 using the electrostatic force. In particular, the substrate chuck 2200 may include a first electrostatic electrode 2210 providing first electrostatic force associated with holding a central portion of the rear surface of the substrate 2010 and a second electrostatic electrode 2220 providing second electrostatic force associated with holding an edge portion of the rear surface of the substrate 2010. The first electrostatic electrode 2210 and the second electrostatic electrode 2220 may be disposed in the substrate chuck 2200. For example, the second electrostatic electrode 2220 may have a circular ring shape and surround the first electrostatic electrode 2210. Each of the first electrostatic electrode 2210 and the second electrostatic electrode 2220 may be formed of a metal material such as, for example, tungsten (W) or molybdenum (Mo), and the substrate chuck 2200 may be formed of a ceramic material such as, for example, aluminum oxide (Al₂O₃), aluminum nitride (AlN), or yttrium oxide (Y₂O₃).

The substrate chuck 2200 may be connected to a power supply unit 2230 for applying a first electrostatic voltage and a second electrostatic voltage to the first electrostatic electrode 2210 and the second electrostatic electrode 2220, respectively. For example, the power supply unit 2230 may apply a positive voltage to the first electrostatic electrode 2210 and apply a negative voltage to the second electrostatic electrode 2220. However, unlike described herein, the first electrostatic voltage and the second electrostatic voltage may also have the same polarity.

According to an embodiment of the present disclosure, the power supply unit 2230 may first apply the first electrostatic voltage to the first electrostatic electrode 2210, based on which the substrate chuck 2200 may hold the central portion of the rear surface of the substrate 2010 on a central portion of a lower surface of the substrate chuck 2200. The power supply unit 2230 may then apply the second electrostatic voltage to the second electrostatic electrode 2220, based on which the substrate chuck 2200 may hold the edge portion of the rear surface of the substrate 2010 on an edge portion of the lower surface of the substrate chuck 2200. That is, the substrate chuck 2200 may first hold the central portion of the rear surface of the substrate 2010, and then hold the edge portion of the rear surface of the substrate 2010. Accordingly, the rear surface of the substrate 2010 may be in entirely uniformly close contact with the lower surface of the substrate chuck 2200.

A plurality of lift fingers 2250 for loading the substrate 2010 onto the substrate chuck 2200 may be disposed in the process chamber 2100. The lift fingers 2250 may be disposed around the substrate chuck 2200 and the mask chuck 2300, and may be moved in a vertical direction by finger drivers 2260, respectively. For example, three or four lift fingers 2250 may be disposed around the substrate chuck 2200 and the mask chuck 2300. The substrate 2010 may be carried into the process chamber 2100 by a transfer robot (not illustrated), and may be transferred from the transfer robot onto the lift fingers 2250 under the substrate chuck 2200. In this case, the rear surface of the substrate 2010 may face the lower surface of the substrate chuck 2200, and the lift fingers 2250 may support edge portions of the front surface of the substrate 2010. The finger driver 2260 may raise the lift fingers 2250 such that the substrate 2010 is adjacent to the lower surface of the substrate chuck 2200, and the central portion and the edge portion of the rear surface of the substrate 2010 may be sequentially held on the lower surface of the substrate chuck 2200 by the first electrostatic force and the second electrostatic force.

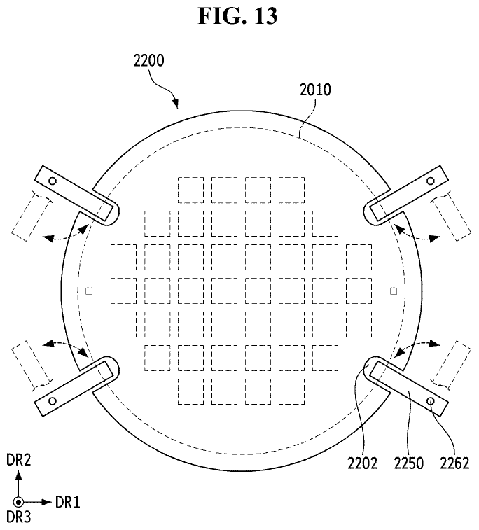

FIG. 13 is a schematic plan view illustrating the substrate chuck and lift fingers illustrated in FIG. 11.

Referring to FIGS. 11 to 13, the finger driver 2260 may be disposed on an upper lid of the process chamber 2100, and may be respectively connected to the lift fingers 2250 through drive shafts 2262 extending in the vertical direction through the upper lid of the process chamber 2100. The finger drivers 2260 may move the lift fingers 2250 in the vertical direction in order to load or unload the substrate 2010. In some aspects, the finger drivers 2260 may rotate the lift fingers 2250 based on the drive shafts 2262, respectively. For example, the finger drivers 2260 may rotate the lift fingers 2250 such that ends of the lift fingers 2250 do not overlap the substrate chuck 2200, enabling vertical movement of the lift fingers 2250. In some aspects, the finger driver 2260 may rotate the lift fingers 2250 such that the ends of the lift fingers 2250 overlap the edge portions of the substrate 2010 and support the edge portions of the substrate 2010.

The finger driver 2260 may raise the lift fingers 2250 in a state in which the edge portions of the substrate 2010 are supported by the ends of the lift fingers 2250, as illustrated in FIG. 12, and accordingly, the substrate 2010 may be loaded onto the lower surface of the substrate chuck 2200. After the substrate 2010 is loaded onto the lower surface of the substrate chuck 2200, the power supply unit 2230 may sequentially apply the first electrostatic voltage and the second electrostatic voltage to the first electrostatic electrode 2210 and the second electrostatic electrode 2220, and accordingly, the substrate 2010 may be held on the lower surface of the substrate chuck 2200.

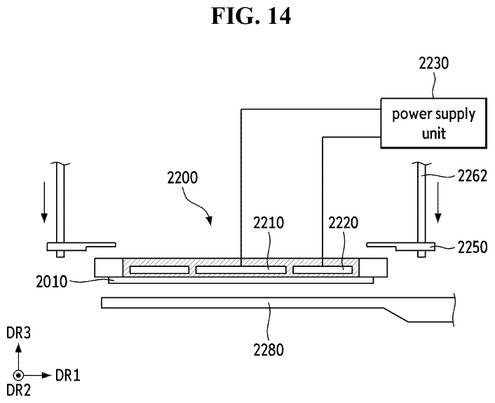

FIG. 14 is a schematic cross-sectional view illustrating a method of unloading a substrate from the substrate chuck illustrated in FIG. 11.

Referring to FIGS. 13 and 14, the power supply unit 2230 may apply a first reverse voltage and a second reverse voltage to the first electrostatic electrode 2210 and the second electrostatic electrode 2220, respectively, in order to unload the substrate 2010 from the substrate chuck 2200, that is, in order to separate the substrate 2010 from the substrate chuck 2200. For example, the power supply unit 2230 may apply a negative voltage to the first electrostatic electrode 2210 and apply a positive voltage to the second electrostatic electrode 2220. In this case, a robot arm 2280 of the transfer robot may be positioned under the substrate chuck 2200, and the substrate 2010 separated from the substrate chuck 2200 may be transferred onto the robot arm 2280 of the transfer robot.

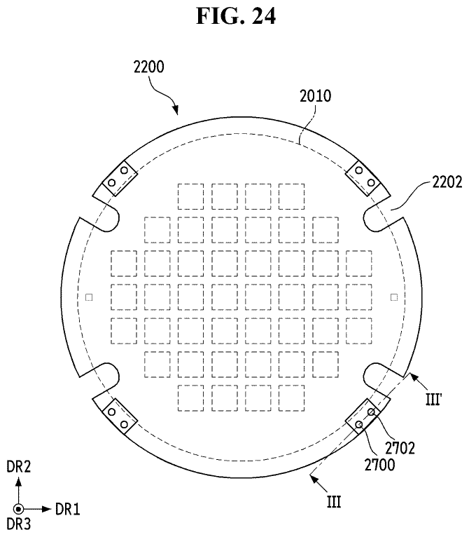

According to an embodiment of the present disclosure, a plurality of slots 2202 may be provided in the vertical direction at side portions of the substrate chuck 2200 and enable raising/lowering movement, that is, vertical movement, of the lift fingers 2250. Example aspects of the slots 2202 are illustrated at FIG. 24. The finger drivers 2260 may raise the lift fingers 2250 such that the lift fingers 2250 are positioned above the substrate chuck 2200, and may then rotate the lift fingers 2250 such that the ends of the lift fingers 2250 overlap the edge portions of the substrate 2010. After the first reverse voltage and the second reverse voltage are applied from the power supply unit 2230 to the first electrostatic electrode 2210 and the second electrostatic electrode 2220, respectively, the finger drivers 2260 may lower the lift fingers 2250. In this case, the lift fingers 2250 may be lowered through the slots 2202 of the substrate chuck 2200, and the substrate 2010 may be quickly separated from the substrate chuck 2200 by the ends of the lift fingers 2250. In some embodiments, as illustrated in FIG. 13, the substrate chuck 2200 has a disk shape, but alternatively, the substrate chuck 2200 may have a square plate shape.

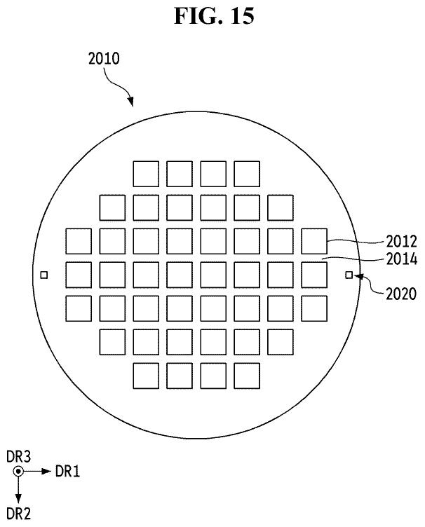

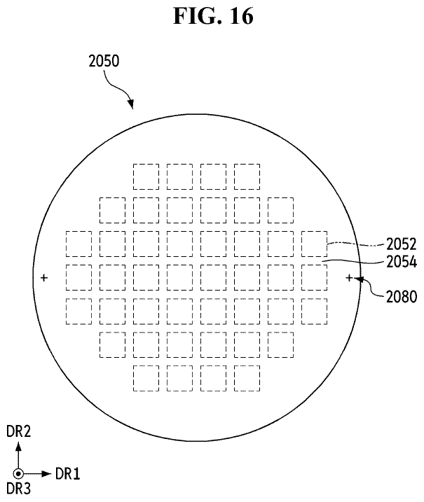

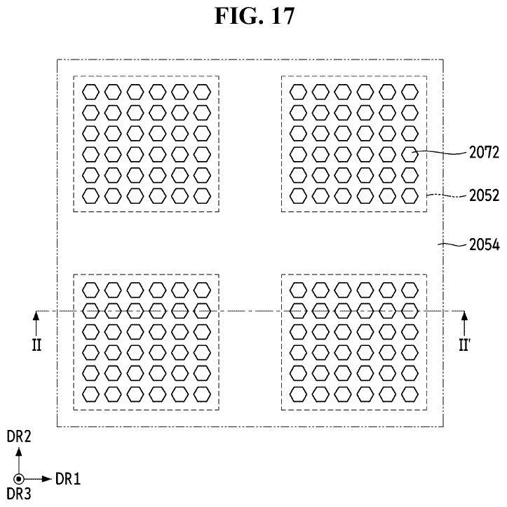

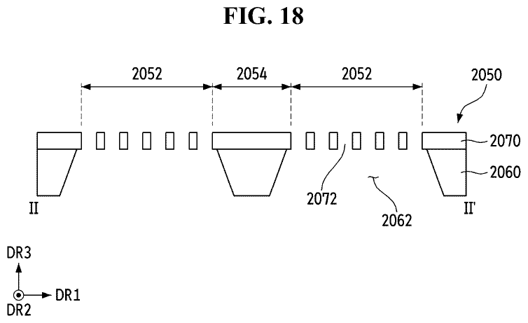

FIG. 15 is a schematic bottom view illustrating a substrate illustrated in FIG. 11, and FIG. 16 is a schematic plan view illustrating a deposition mask illustrated in FIG. 11. FIG. 17 is a schematic enlarged plan view illustrating mask cell regions illustrated in FIG. 16, and FIG. 18 is a schematic cross-sectional view taken along line II-II′ illustrated in FIG. 17.

Referring to FIGS. 15 to 18, the substrate 2010 may include a plurality of display cell regions 2012 and a scribe lane region 2014 disposed between the display cell regions 2012. The display cell regions 2012 may be arranged in a matrix form along a first direction DR1 and a second direction DR2 crossing the first direction DR1, as illustrated in FIG. 15. The display cell regions 2012 may be individualized into a plurality of display panels 100 through a dicing process after a display manufacturing process is completed. For example, the first direction DR1 may be a first horizontal direction, and the second direction DR2 may be a second horizontal direction perpendicular to the first direction DR1. In this case, the first direction DR1 may be an X-axis direction, and the second direction DR2 may be a Y-axis direction.

Each of the display cell regions 2012 may include the semiconductor backplane SBP (see FIG. 7), the light emitting element backplane EBP (see FIG. 7) disposed on the semiconductor backplane SBP, the reflective electrode layer RL (see FIG. 7) disposed on the light emitting element backplane EBP, and the insulating film INS10 (see FIG. 7) disposed on the reflective electrode layer RL. In some aspects, each of the display cell regions 2012 may include a plurality of electrode patterns such as, for example, a plurality of anode electrodes AND, disposed on the insulating film INS10, and the anode electrodes AND may be connected to the reflective electrode layer RL through a plurality of vias VA10. In this case, the electrode patterns of the display cell regions 2012 may be disposed on the front surface of the substrate 2010, and the substrate chuck 2200 may hold the rear surface of the substrate 2010 such that the electrode patterns of the display cell regions 2012 face downward, that is, face the deposition source 2150.

The deposition mask 2050 may include mask cell regions 2052 respectively corresponding to the display cell regions 2012 of the substrate 2010 and a grid region 2054 disposed between the mask cell regions 2052. Each of the mask cell regions 2052 may have a plurality of pixel openings 2072 exposing the anode electrodes in a deposition process. For example, the deposition mask 2050 may include a mask frame 2060 and a membrane 2070 disposed on the mask frame 2060, and the pixel openings 2072 may be formed to penetrate through the mask cell regions 2052 of the membrane 2070. In this case, the mask frame 2060 may have cell openings 2062 respectively exposing the mask cell regions 2052 of the membrane 2070, and the pixel openings 2072 may be in communication with the cell openings 2062. That is, the mask cell regions 2052 may be disposed on the cell openings 2062, respectively.

The mask cell regions 2052 may be arranged in a matrix form along the first direction DR1 and the second direction DR2 crossing the first direction DR1, as illustrated in FIG. 16. For example, the mask cell regions 2052 may be arranged in a matrix form along the first horizontal direction and the second horizontal direction perpendicular to the first horizontal direction, and may be arranged to correspond to the display cell regions 2012 of the substrate 2010, respectively.

The cell openings 2062 of the mask frame 2060 may be formed through an etching process such that the mask cell regions 2052 of the membrane 2070 are exposed after the pixel openings 2072 of the membrane 2070 are formed. For example, a semiconductor substrate such as, for example, a silicon wafer may be used as the mask frame 2060, and the cell openings 2062 may be formed through a wet etching process using tetramethyl ammonium hydroxide (TMAH), potassium hydroxide (KOH), or the like.

The membrane 2070 may be formed of an inorganic material such as, for example, silicon nitride and may be formed through a thermal chemical vapor deposition (TCVD) process. The pixel openings 2072 of the membrane 2070 may be formed to correspond to the anode electrodes AND on the substrate 2010. For example, the pixel openings 2072 penetrating through the membrane 2070 may be formed by forming a photoresist pattern (not illustrated) exposing portions where the pixel openings 2072 are to be formed on the membrane 2070 and performing an anisotropic etching process using the photoresist pattern as an etching mask. However, configurations of the mask frame 2060 and the membrane 2070 may be variously changed, and thus, the scope of the present disclosure is not limited by those described herein.

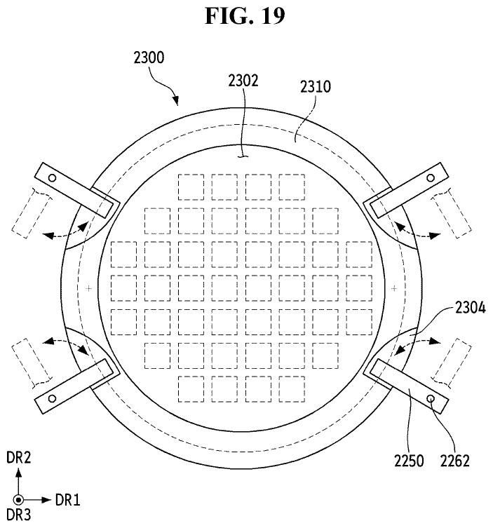

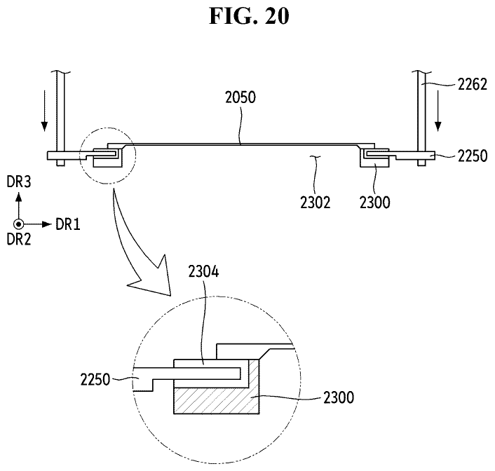

FIG. 19 is a schematic plan view illustrating a mask chuck illustrated in FIG. 11, and FIG. 20 is a schematic cross-sectional view illustrating the mask chuck illustrated in FIG. 11.

Referring to FIGS. 19 and 20, the mask chuck 2300 may be disposed in a horizontal direction under the substrate chuck 2200 in the process chamber 2100. The mask chuck 2300 may support an edge portion of the deposition mask 2050, and may have a circular opening 2302 such that the cell openings 2062 of the deposition mask 2050 are exposed toward the deposition source 2150. For example, as illustrated in FIG. 19, the mask chuck 2300 may have a circular ring shape. However, unlike described herein, the mask chuck 2300 may also have a square plate shape with a circular opening.

The deposition mask 2050 may be carried into the process chamber 2100 by a transfer robot, and may be transferred onto the lift fingers 2250 above the mask chuck 2300. The edge portions of the deposition mask 2050 may be placed on the ends of the lift fingers 2250, and the finger drivers 2260 may lower the lift fingers 2250 in order to load the deposition mask 2050 onto the mask chuck 2300. In this case, edge portions of an upper surface of the mask chuck 2300 may be provided with recesses 2304 into which the lift fingers 2250 are inserted, and the finger drivers 2260 may rotate the lift fingers 2250 such that the lift fingers 2250 do not overlap the mask chuck 2300 after the deposition mask 2050 is loaded onto the mask chuck 2300.

The mask chuck 2300 may hold the edge portion of the deposition mask 2050 using electrostatic force. For example, the mask chuck 2300 may include a chucking region 2310 with a circular ring shape for holding the edge portion of the deposition mask 2050 using the electrostatic force. Although not illustrated in detail, the chucking region 2310 may include at least one electrostatic electrode (not illustrated) for providing the electrostatic force. For example, the chucking region 2310 may include a third electrostatic electrode and a fourth electrostatic electrode, and the power supply unit 2230 may apply a third electrostatic voltage and a fourth electrostatic voltage to the third electrostatic electrode and the fourth electrostatic electrode, respectively, associated with holding the deposition mask 2050.

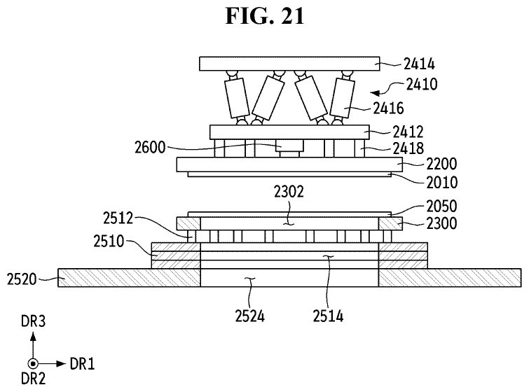

FIG. 21 is a schematic view illustrating a substrate chuck driver and a mask chuck driver illustrated in FIG. 11.

Referring to FIGS. 11 and 21, the deposition apparatus 2000 may include a substrate chuck driver 2400 moving the substrate chuck 2200 and a mask chuck driver 2500 moving the mask chuck 2300. For example, the substrate chuck driver 2400 may move the substrate chuck 2200 in the first direction DR1, the second direction DR2, and a third direction DR3 associated with adjusting a position of the substrate 2010. In this case, the first direction DR1 may be a first horizontal direction, the second direction DR2 may be a second horizontal direction perpendicular to the first direction DR1, and the third direction DR3 may be a vertical direction. That is, the first direction DR1, the second direction DR2, and the third direction DR3 may be an X-axis direction, a Y-axis direction, and a Z-axis direction, respectively.

The substrate chuck driver 2400 may rotate the substrate chuck 2200 around a Z-axis associated with adjusting an azimuth of the substrate 2010. In some aspects, the substrate chuck driver 2400 may rotate the substrate chuck 2200 around an X-axis and may rotate the substrate chuck 2200 around a Y-axis, associated with adjusting a gradient of the substrate 2010. For example, the substrate chuck driver 2400 may include a hexapod actuator 2410 providing motion of six degrees of freedom (X, Y, Z, θx, θy, and θz).

The substrate chuck driver 2400 may include a substrate stage 2420 on which the hexapod actuator 2410 is mounted and a second actuator 2430 connected to the substrate stage 2420. The substrate stage 2420 may be disposed in the horizontal direction in the process chamber 2100, and the second actuator 2430 may be disposed above the process chamber 2100. The second actuator 2430 may be connected to the substrate stage 2420 by a plurality of drive shafts 2432 extending in the third direction DR3, that is, the vertical direction (Z-axis direction) through the upper lid of the process chamber 2100, and may move the substrate stage 2420 in a central axis direction of the hexapod actuator 2410, that is, the vertical direction. For example, the second actuator 2430 may be configured using a brushless direct current (DC) motor, a linear motor, a direct drive (DD) motor, or the like, and may adjust a height of the substrate chuck 2200 in order to load or unload the substrate 2010.

The hexapod actuator 2410 may include a first platform 2412 connected to the substrate chuck 2200, a second platform 2414 mounted on the substrate stage 2420, and six sub-actuators 2416 disposed between the first platform 2412 and the second platform 2414. For example, each of the six sub-actuators 2416 may be configured using a brushless DC motor, a voice coil linear motor, a step motor, a DD motor, a servo motor, or the like. As illustrated in FIGS. 11 and 21, the second platform 2414 is disposed on the substrate stage 2420 and the substrate stage 2420 has an opening through which the six sub-actuators 2416 pass, but unlike described herein, the second platform 2414 may be mounted on a lower surface of the substrate stage 2420.

The substrate chuck 2200 may be connected to the first platform 2412 of the hexapod actuator 2410 through a plurality of connection members 2418, and the six sub-actuators 2416 may move and rotate the first platform 2412 associated with adjusting a position of the substrate 2010 in the horizontal direction, a position of the substrate 2010 in the vertical direction, the azimuth of the substrate 2010, and the gradient of the substrate 2010.

The mask chuck driver 2500 may move and rotate the mask chuck 2300 associated with adjusting a position of the deposition mask 2050 in the horizontal direction and an azimuth of the deposition mask 2050. The mask chuck driver 2500 may move the mask chuck 2300 in a direction parallel to the deposition mask 2050 and rotate the mask chuck 2300 based on a central axis of the mask chuck 2300. For example, the mask chuck driver 2500 may move the mask chuck 2300 in the first direction DR1 (X-axis) and the second direction DR2 (Y-axis), and may rotate the mask chuck 2300 based on the third direction DR3 (Z-axis).

The mask chuck driver 2500 may include, for example, a piezo actuator 2510 providing motion of three degrees of freedom (X, Y, and Oz), and the piezo actuator 2510 may have an opening 2514 that is in communication with the circular opening 2302 of the mask chuck 2300. For example, the mask chuck 2300 may be disposed such that the mask chuck 2300 is spaced apart from the piezo actuator 2510 in an upward direction by a predetermined distance. As illustrated in FIG. 21, a plurality of support members 2512 may be disposed on the piezo actuator 2510, and the mask chuck 2300 may be disposed on the plurality of support members 2512. However, a support structure of the mask chuck 2300 may be variously changed, and thus, the scope of the present disclosure is not limited thereby.

The mask chuck driver 2500 may include a mask stage 2520 disposed in the horizontal direction in the process chamber 2100 and supporting the piezo actuator 2510. For example, the mask stage 2520 may have an opening 2524 that is in communication with the opening 2514 of the piezo actuator 2510, and may be supported by a plurality of posts 2522 (see FIG. 11) connected to the upper lid of the process chamber 2100. However, a support structure of the mask stage 2520 may be variously changed, and thus, the scope of the present disclosure is not limited thereby.

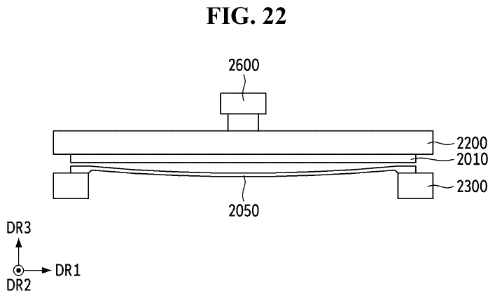

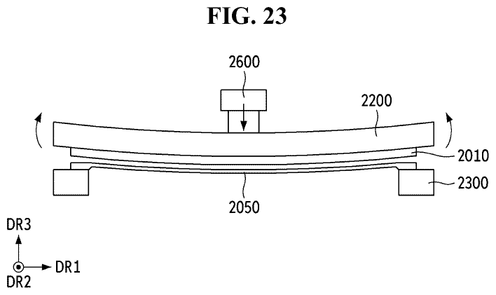

FIGS. 22 and 23 are schematic views illustrating a chuck pressurizing portion, the substrate, and the deposition mask illustrated in FIG. 21.

Referring to FIGS. 21 to 23, the deposition apparatus 2000 according to an embodiment of the present disclosure may include a chuck pressurizing portion 2600 pressurizing a central portion of the substrate chuck 2200 such that the substrate chuck 2200 is convexly deformed toward the deposition mask 2050. The chuck pressurizing portion 2600 may be used to make a gap between the substrate 2010 and the deposition mask 2050 uniform and improve parallelism between the substrate 2010 and the deposition mask 2050. The term “parallelism” between two elements as described herein may refer to a state or condition in which the two elements (e.g., features, surfaces) are equidistant from each other at all points such that the two elements maintain a constant distance apart and do not converge or diverge. Descriptions herein of improving parallelism between the substrate 2010 and the deposition mask 2050 include applying the techniques described herein such that the substrate 2010 and the deposition mask 2050 are a constant distance apart and do not converge or diverge.

Specifically, during the deposition process, as illustrated in FIG. 22, global warpage in which the deposition mask 2050 is entirely deformed or cell warpage in which the mask cell regions 2052 are deformed may occur. Accordingly, the gap between the substrate 2010 and the deposition mask 2050 may become non-uniform and the parallelism between the substrate 2010 and the deposition mask 2050 may deteriorate. The global warpage and the cell warpage may occur in a manufacturing process of the deposition mask 2050. Accordingly, pixel position accuracy PPA of light emitting layers EML1, EML2, and EML3 formed on the substrate 2010 may deteriorate, and a color mixing phenomenon between adjacent sub-pixels SP1, SP2, and SP3 may occur.

According to an embodiment of the present disclosure, the chuck pressurizing portion 2600 may be disposed above the substrate chuck 2200, and may apply pressure to the central portion of the substrate chuck 2200 in a downward direction (e.g., in the negative third direction DR3). For example, a piezo actuator may be used as the chuck pressurizing portion 2600, and may be disposed between the first platform 2412 of the hexapod actuator 2410 and the substrate chuck 2200. Specifically, the chuck pressurizing portion 2600 may be mounted on the first platform 2412 of the hexapod actuator 2410, and may press the central portion of the substrate chuck 2200 toward the deposition mask 2050.

The chuck pressurizing portion 2600 may apply pressure to the central portion of the substrate chuck 2200 such that the substrate chuck 2200 is deformed within an elastic limit. For example, based on the pressure applied by the chuck pressurizing portion 2600, the central portion of the substrate chuck 2200 may convexly protrude toward the deposition mask 2050 by a displacement amount of about 0.5 μm to about 2 μm. Accordingly, as illustrated in FIG. 23, the gap between the substrate 2010 and the deposition mask 2050 may become uniform, and the parallelism between the substrate 2010 and the deposition mask 2050 may be significantly improved.

According to an embodiment of the present disclosure, the deposition apparatus 2000 may include a plurality of gap sensors measuring a gap between the substrate chuck 2200 and the mask chuck 2300. For example, the gap sensors may be disposed on the substrate chuck 2200 and measure a distance to the mask chuck 2300.

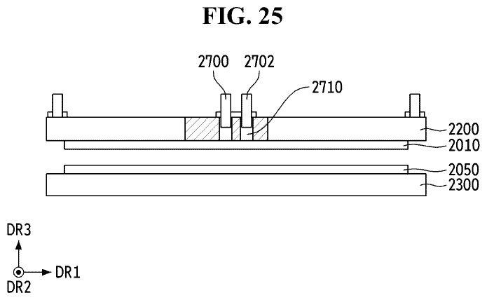

FIG. 24 is a schematic plan view illustrating gap sensors disposed on the substrate chuck, and FIG. 25 is a schematic cross-sectional view taken along line III-III′ illustrated in FIG. 24.

Referring to FIGS. 24 and 25, a plurality of gap sensors 2700 and 2702 for measuring the gap between the substrate chuck 2200 and the mask chuck 2300 may be disposed on the substrate chuck 2200. In this case, a plurality of measurement holes 2710 may be provided in the substrate chuck 2200, and the gap sensors 2700 and 2702 may measure the distance to the mask chuck 2300 through the measurement holes 2710. For example, after the substrate 2010 and the deposition mask 2050 are loaded onto the substrate chuck 2200 and the mask chuck 2300, respectively, the second actuator 2430 may lower the substrate chuck 2200 such that the substrate 2010 is adjacent to the deposition mask 2050. Then, the hexapod actuator 2410 may adjust the gap between the substrate 2010 and the deposition mask 2050. After the gap between the substrate 2010 and the deposition mask 2050 is adjusted, the gap sensors 2700 and 2702 may measure the distance to the mask chuck 2300, and the hexapod actuator 2410 may adjust a gradient of the substrate chuck 2200 based on measured values provided by the gap sensors 2700 and 2702 associated with adjusting the parallelism between the substrate 2010 and the deposition mask 2050.

According to an embodiment of the present disclosure, a plurality of first gap sensors 2700 may be disposed on the substrate chuck 2200, and the hexapod actuator 2410 may move the substrate chuck 2200 such that the substrate 2010 is spaced apart from the deposition mask 2050 by a first gap, and then may primarily adjust the gradient of the substrate chuck 2200 based on measured values provided by the first gap sensors 2700 in order to primarily adjust the parallelism between the substrate 2010 and the deposition mask 2050. For example, capacitive proximity sensors may be used as the first gap sensors 2700. The hexapod actuator 2410 may lower the substrate chuck 2200 such that the gap between the substrate 2010 and the deposition mask 2050 is about 100 μm to about 200 μm, and then adjust the gradient of the substrate chuck 2200 based on the measured values provided by the first gap sensors 2700.

In some aspects, a plurality of second gap sensors 2702 may be disposed on the substrate chuck 2200. For example, confocal sensors having a higher resolution than the first gap sensors 2700 may be used as the second gap sensors 2702. In this case, the hexapod actuator 2410 may move the substrate chuck 2200 such that the substrate 2010 is spaced apart from the deposition mask 2050 by a second gap smaller than the first gap, and then may secondarily adjust the gradient of the substrate chuck 2200 based on measured values provided by the second gap sensors 2702 in association with secondarily adjusting the parallelism between the substrate 2010 and the deposition mask 2050. For example, the hexapod actuator 2410 may lower the substrate chuck 2200 such that the gap between the substrate 2010 and the deposition mask 2050 is about 10 μm to about 50 μm, and then adjust the gradient of the substrate chuck 2200 based on the measured values provided by the second gap sensors 2702.

The first gap sensors 2700 and the second gap sensors 2702 may be disposed adjacent to each other on edge portions of the substrate chuck 2200. For example, as illustrated in FIG. 24, four first gap sensors 2700 and four second gap sensors 2702 may be used. However, positions and numbers of first and second gap sensors 2700 and 2702 may be variously changed, and thus, the scope of the present disclosure is not limited thereby.

After the parallelism between the substrate 2010 and the deposition mask 2050 is adjusted as described herein, an alignment process between the substrate 2010 and the deposition mask 2050 may be performed. Referring to FIGS. 15 and 16, a substrate alignment key 2020 and a mask alignment key 2080 for alignment may be provided on the substrate 2010 and the deposition mask 2050, respectively. For example, two substrate alignment keys 2020 may be disposed on the edge portions of the substrate 2010, and two mask alignment keys 2080 may be disposed on the edge portions of the deposition mask 2050. However, the numbers of substrate alignment keys 2020 and mask alignment keys 2080 may be variously changed, and thus, the scope of the present disclosure is not limited thereby.

Referring to FIG. 11 again, the deposition apparatus 2000 may include a camera 2800 for detecting the substrate alignment keys 2020 and the mask alignment keys 2080. For example, the deposition apparatus 2000 may include two cameras 2800 for detecting the substrate alignment keys 2020 and the mask alignment keys 2080.

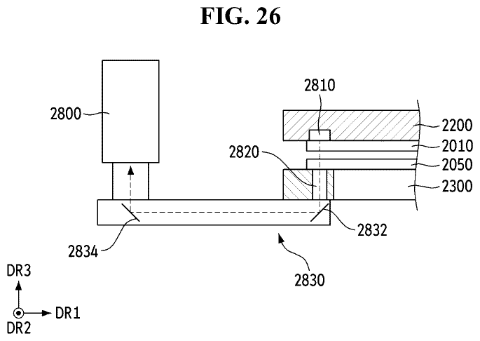

FIG. 26 is a schematic enlarged cross-sectional view illustrating an illumination portion and a camera illustrated in FIG. 11.

Referring to FIG. 26, the camera 2800 for detecting the substrate alignment key 2020 and the mask alignment key 2080 may be disposed on one side of the mask chuck 2300. According to an embodiment of the present disclosure, the deposition apparatus 2000 may include an illumination portion 2810 providing light that may be transmitted through the substrate 2010 and the deposition mask 2050, and the camera 2800 may be disposed to detect the light transmitted through the substrate 2010 and the deposition mask 2050. For example, the light provided from the illumination portion 2810 may be transmitted through a portion of the substrate 2010 where the substrate alignment key 2020 is disposed and a portion of the deposition mask 2050 where the mask alignment key 2080 is disposed.

The illumination portion 2810 may be disposed within an edge portion of the lower surface of the substrate chuck 2200, and may provide infrared light that may be transmitted through the substrate 2010 and the deposition mask 2050. For example, the illumination portion 2810 may include an infrared lamp mounted in the substrate chuck 2200, and a through hole 2820 passing the light transmitted through the substrate 2010 and the deposition mask 2050 therethrough may be provided at an edge portion of the mask chuck 2300. The infrared lamp may provide near infrared (NIR) or shortwave infrared (SWIR) light, and the light transmitted through the substrate 2010 and the deposition mask 2050 may be guided to the camera 2800 via an optical unit 2830 (or a prism unit) disposed under the mask chuck 2300. For example, the infrared lamp may provide infrared light having a wavelength of about 1010 nm to about 1020 nm.

The optical unit 2830 may include reflectors 2832 and 2834 for guiding the light transmitted through the substrate 2010 and the deposition mask 2050 to the camera 2800, and the camera 2800 may acquire image information from the light guided through the optical unit 2830. In particular, the image information may include position information of the substrate alignment key 2020 and the mask alignment key 2080, and the substrate chuck driver 2400 and/or the mask chuck driver 2500 may move and/or rotate the substrate chuck 2200 and/or the mask chuck 2300 in association with aligning the substrate 2010 and the deposition mask 2050 with each other based on the image information acquired by the camera 2800.

For example, the hexapod actuator 2410 of the substrate chuck driver 2400 may move the substrate chuck 2200 in the first direction DR1 and the second direction DR2 and rotate the substrate chuck 2200 based on the third direction DR3, based on the image information. The piezo actuator 2510 of the mask chuck driver 2500 may move the mask chuck 2300 in the first direction DR1 and the second direction DR2 and rotate the mask chuck 2300 based on the third direction DR3, based on the image information. The alignment process between the substrate 2010 and the deposition mask 2050 may be performed by the hexapod actuator 2410 of the substrate chuck driver 2400 or the piezo actuator 2510 of the mask chuck driver 2500. As another example, the alignment process between the substrate 2010 and the deposition mask 2050 may be performed by both the hexapod actuator 2410 of the substrate chuck driver 2400 and the piezo actuator 2510 of the mask chuck driver 2500.

In some embodiments, the alignment process between the substrate 2010 and the deposition mask 2050 may be performed after a primary parallelism adjustment process between the substrate 2010 and the deposition mask 2050. However, unlike described herein, the alignment process between the substrate 2010 and the deposition mask 2050 may be performed after a secondary parallelism adjustment process between the substrate 2010 and the deposition mask 2050.

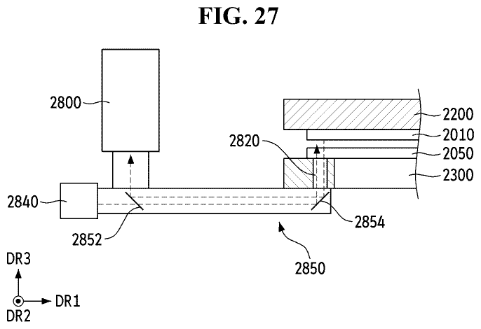

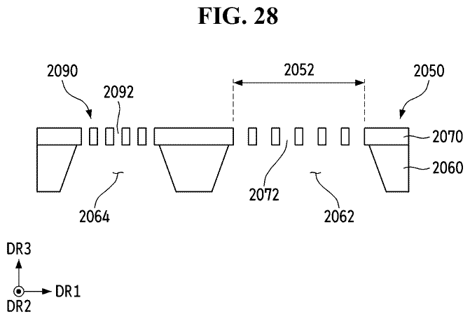

FIG. 27 is a schematic enlarged cross-sectional view illustrating another example of an illumination portion and a camera illustrated in FIG. 26. FIG. 28 is a schematic enlarged cross-sectional view illustrating a deposition mask illustrated in FIG. 27.

Referring to FIGS. 27 and 28, an illumination portion 2840 may provide light onto the substrate 2010 through the deposition mask 2050, and a camera 2800 may detect light reflected from the substrate 2010 and transmitted through the deposition mask 2050. For example, a through hole 2820 passing the light provided from the illumination portion 2840 and the light reflected from the substrate 2010 therethrough may be provided at the edge portion of the mask chuck 2300, and an optical unit 2850 (or a prism unit) guiding the light provided from the illumination portion 2840 onto the substrate 2010 and guiding the light reflected from the substrate 2010 to the camera 2800 may be disposed below the mask chuck 2300.

The light provided from the illumination portion 2840 may be transmitted through the deposition mask 2050 and provided onto the substrate 2010, and the light reflected from the substrate 2010 may be transmitted through the deposition mask 2050 and guided to the camera 2800. In this case, as illustrated in FIG. 28, the membrane 2070 of the deposition mask 2050 may include a mask alignment key 2090, and the mask frame 2060 of the deposition mask 2050 may have a key opening 2064 exposing the mask alignment key 2090. For example, the membrane 2070 may be formed of silicon nitride, and the mask alignment key 2090 may include a plurality of alignment patterns 2092 penetrating through the membrane 2070. In this case, the key openings 2064 may be formed simultaneously with the cell openings 2062 of the mask frame 2060, and the alignment patterns 2092 may be formed simultaneously with the pixel openings 2072 of the membrane 2070.

As an example, the illumination portion 2840 may include a blue light emitting diode (LED) lamp, and the optical unit 2850 may include a beam splitter 2852 and a reflector 2854. The beam splitter 2852 may transmit some of the light provided from the illumination portion 2840 therethrough, and may reflect some of the light reflected from the substrate 2010 toward the camera 2800. The reflector 2854 may reflect the light transmitted through the beam splitter 2852 toward the substrate 2010, and may reflect the light reflected from the substrate 2010 toward the beam splitter 2852.

The substrate alignment key 2020 may be disposed on the substrate 2010, and may be formed of the same material as the electrode patterns disposed on the substrate 2010. For example, the substrate alignment key 2020 may be formed simultaneously with the anode electrodes AND on the substrate 2010. The camera 2800 may acquire image information including position information of the substrate alignment key 2020 and position information of the mask alignment key 2090, and the substrate chuck driver 2400 and/or the mask chuck driver 2500 may move and/or rotate the substrate chuck 2200 and/or the mask chuck 2300 such that the substrate 2010 and the deposition mask 2050 are aligned with each other based on the image information.

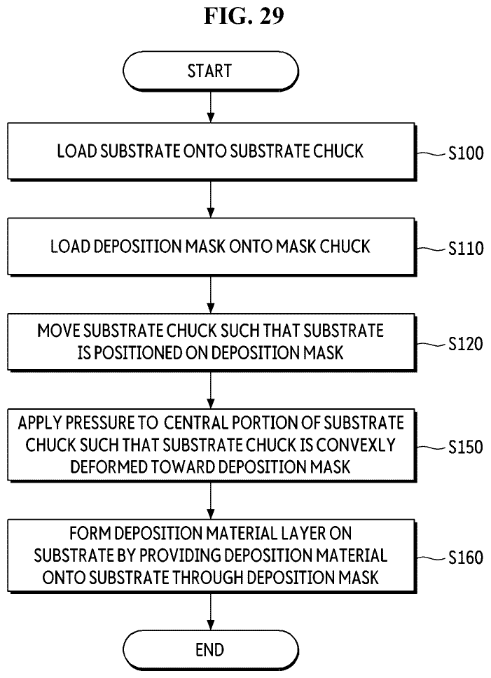

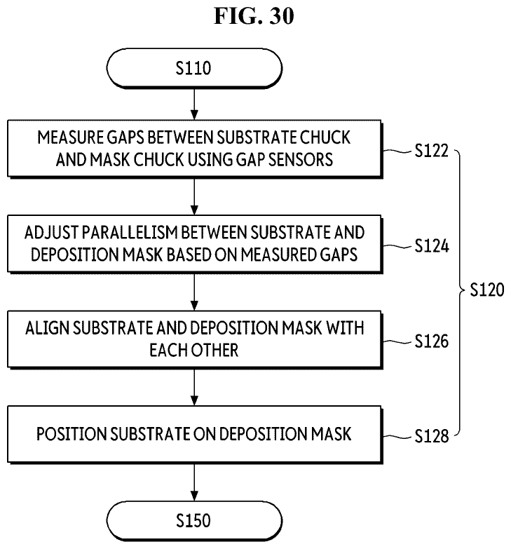

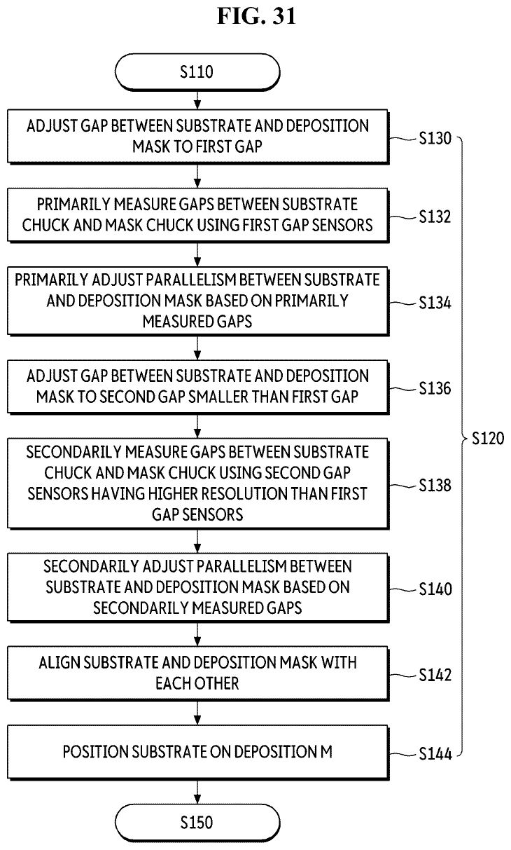

FIG. 29 is a flowchart illustrating a method of manufacturing a display panel according to another embodiment of the present disclosure. FIG. 30 is a flowchart illustrating S120 illustrated in FIG. 29. FIG. 31 is a flowchart illustrating another example of S120 illustrated in FIG. 29.

Referring to FIG. 29, in S100, the method may include loading the substrate 2010 onto the substrate chuck 2200. For example, the substrate 2010 may be carried into the process chamber 2100 by the transfer robot, and may be transferred onto the lift fingers 2250 below the substrate chuck 2200. The substrate 2010 may be placed on the ends of the lift fingers 2250, and the finger drivers 2260 may raise the lift fingers 2250 such that the substrate 2010 is adjacent to the lower surface of the substrate chuck 2200, as illustrated in FIG. 12.

The substrate chuck 2200 may hold the substrate 2010 using the electrostatic force. For example, the substrate chuck 2200 may include the first electrostatic electrode 2210 providing the first electrostatic force for holding the central portion of the substrate 2010 and the second electrostatic electrode 2220 providing the second electrostatic force for holding the edge portion of the substrate 2010. The power supply unit 2230 may apply the first electrostatic voltage to the first electrostatic electrode 2210, based on which the substrate chuck 2200 may hold the central portion of the substrate 2010 on the lower surface of the substrate chuck 2200. The power supply unit 2230 may then apply the second electrostatic voltage to the second electrostatic electrode 2220, based on which the substrate chuck 2200 may hold the edge portion of the substrate 2010 on the lower surface of the substrate chuck 2200.

In S110, the method may include loading the deposition mask 2050 onto the mask chuck 2300. The deposition mask 2050 may be carried into the process chamber 2100 by the transfer robot, and may be transferred onto the lift fingers 2250 above the mask chuck 2300. The deposition mask 2050 may be placed on the ends of the lift fingers 2250, and the finger drivers 2260 may lower the lift fingers 2250 such that the deposition mask 2050 is placed on the mask chuck 2300, as illustrated in FIG. 20. The mask chuck 2300 may hold the edge portion of the deposition mask 2050 using the electrostatic force.

According to that described herein, it has been described that the deposition mask 2050 is loaded onto the mask chuck 2300 after the substrate 2010 is loaded onto the substrate chuck 2200, but conversely, the substrate 2010 may be loaded onto the substrate chuck 2200 after the deposition mask 2050 is loaded onto the mask chuck 2300.

In S120, the method may include moving the substrate chuck 2200 such that the substrate 2010 is positioned on the deposition mask 2050.

Referring to FIG. 30, S120 may include measuring the gaps between the substrate chuck 2200 and the mask chuck 2300 using the plurality of gap sensors 2700 or 2702 (S122) and adjusting the parallelism between the substrate 2010 and the deposition mask 2050 based on the measured gaps (S124).

For example, after the substrate 2010 and the deposition mask 2050 are loaded onto the substrate chuck 2200 and the mask chuck 2300, respectively, the second actuator 2430 may lower the substrate chuck 2200, and then, the hexapod actuator 2410 may adjust a height of the substrate chuck 2200 such that the gap between the substrate 2010 and the deposition mask 2050 becomes a predetermined gap. Then, the gaps between the substrate chuck 2200 and the mask chuck 2300 may be measured by the first gap sensors 2700 or the second gap sensors 2702, and the hexapod actuator 2410 may adjust the gradient of the substrate chuck 2200 based on the measured gaps associated with adjusting the parallelism between the substrate 2010 and the deposition mask 2050.

After the parallelism between the substrate 2010 and the deposition mask 2050 is adjusted as described herein, the method may include aligning the substrate 2010 and the deposition mask 2050 with each other in S126. For example, as illustrated in FIG. 26, the light transmitted through the substrate 2010 and the deposition mask 2050 may be provided using the illumination portion 2810, and the light transmitted through the substrate 2010 and the deposition mask 2050 may be detected by the camera 2800. In this case, the illumination portion 2810 may provide near infrared (NIR) or shortwave infrared (SWIR) light. As an example, the illumination portion 2810 may provide infrared light having a wavelength of about 1010 nm to about 1020 nm. The camera 2800 may acquire image information from the detected light, and the image information may include the position information of the substrate alignment key 2020 and the position information of the mask alignment key 2080. Then, the hexapod actuator 2410 of the substrate chuck driver 2400 and/or the piezo actuator 2510 of the mask chuck driver 2500 may align the substrate 2010 and the deposition mask 2050 with each other using the image information.

As another example, as illustrated in FIG. 27, the illumination portion 2840 may provide the light onto the substrate 2010 through the deposition mask 2050, and the light reflected from the substrate 2010 and transmitted through the deposition mask 2050 may be detected by the camera 2800. In this case, the illumination portion 2840 may provide blue light, and the camera 2800 may acquire image information from the detected light. The image information may include the position information of the substrate alignment key 2020 and the position information of the mask alignment key 2090, and the hexapod actuator 2410 of the substrate chuck driver 2400 and/or the piezo actuator 2510 of the mask chuck driver 2500 may align the substrate 2010 and the deposition mask 2050 with each other using the image information.

After the substrate 2010 and the deposition mask 2050 are aligned with each other as described herein, the method may include positioning the substrate 2010 on the deposition mask 2050 in S128. For example, the hexapod actuator 2410 may lower the substrate chuck 2200 such that the substrate 2010 is in close contact with the deposition mask 2050. As another example, the hexapod actuator 2410 may adjust a height of the substrate chuck 2200 such that the gap between the substrate 2010 and the deposition mask 2050 becomes a predetermined gap, for example, a gap of about several micrometers.

As another example, referring to FIG. 31, S120 may include adjusting a gap between the substrate 2010 and the deposition mask 2050 to a first gap (S130), primarily measuring gaps between the substrate chuck 2200 and the mask chuck 2300 using the plurality of first gap sensors 2700 (S132), primarily adjusting parallelism between the substrate 2010 and the deposition mask 2050 based on the primarily measured gaps (S134), adjusting the gap between the substrate 2010 and the deposition mask 2050 to a second gap smaller than the first gap (S136), secondarily measuring the gaps between the substrate chuck 2200 and the mask chuck 2300 using the plurality of second gap sensors 2702 having a higher resolution than the first gap sensors 2700 (S138), and secondarily adjusting the parallelism between the substrate 2010 and the deposition mask 2050 based on the secondarily measured gaps (S140).

Specifically, after the substrate 2010 and the deposition mask 2050 are loaded onto the substrate chuck 2200 and the mask chuck 2300, respectively, the second actuator 2430 may lower the substrate chuck 2200, and then, the hexapod actuator 2410 may adjust a height of the substrate chuck 2200 such that the substrate 2010 and the deposition mask 2050 are spaced apart by the first gap. For example, the hexapod actuator 2410 may adjust the height of the substrate chuck 2200 such that the gap (i.e., first gap) between the substrate 2010 and the deposition mask 2050 is about 100 μm to about 200 μm. Then, the gaps between the substrate chuck 2200 and the mask chuck 2300 may be primarily measured by the first gap sensors 2700 such as, for example, the capacitive proximity sensors, and the hexapod actuator 2410 may primarily adjust the gradient of the substrate chuck 2200 based on the primarily measured gaps in order to primarily adjust the parallelism between the substrate 2010 and the deposition mask 2050.

Subsequently, the hexapod actuator 2410 may adjust the height of the substrate chuck 2200 such that the substrate 2010 and the deposition mask 2050 are spaced apart by the second gap smaller than the first gap. For example, the hexapod actuator 2410 may adjust the height of the substrate chuck 2200 such that the gap (i.e., second gap) between the substrate 2010 and the deposition mask 2050 is about 10 μm to about 50 μm. Then, the gaps between the substrate chuck 2200 and the mask chuck 2300 may be secondarily measured by the second gap sensors 2702 such as, for example, the confocal sensors, and the hexapod actuator 2410 may secondarily adjust the gradient of the substrate chuck 2200 based on the secondarily measured gaps in order to secondarily adjust the parallelism between the substrate 2010 and the deposition mask 2050.

After the parallelism between the substrate 2010 and the deposition mask 2050 is primarily and secondarily adjusted as described herein, the method may include aligning the substrate 2010 and the deposition mask 2050 with each other in S142, and positioning the substrate 2010 on the deposition mask 2050 in S144. In this case, S142 and S144 are substantially the same as S126 and S128 described herein with reference to FIG. 30, and a description of S142 and S144 is thus omitted.

As another example, the method may include performing S142 after S134. In this case, the method may include performing S136 to S140 after S142, and performing S144 after S140. Specifically, after performing S130 to S134 for primarily adjusting the parallelism between the substrate 2010 and the deposition mask 2050, the method may include performing S142 for aligning the substrate 2010 and the deposition mask 2050 with each other. Then, the method may include performing S136 to S140 for secondarily adjusting the parallelism between the substrate 2010 and the deposition mask 2050 and performing S144 for positioning the substrate 2010 on the deposition mask 2050.

Referring to FIG. 29 again, after the substrate 2010 is positioned on the deposition mask 2050, the method may include applying pressure to the central portion of the substrate chuck 2200 such that the substrate chuck 2200 is convexly deformed toward the deposition mask 2050 in S150. Specifically, the chuck pressurizing portion 2600 may apply pressure to the central portion of the substrate chuck 2200 such that the substrate chuck 2200 is deformed within an elastic limit, as illustrated in FIGS. 22 and 23, and accordingly, the central portion of the substrate chuck 2200 may convexly protrude toward the deposition mask 2050. For example, based on the pressure applied to the central portion of the substrate chuck 2200 by the chuck pressurizing portion 2600, the central portion of the substrate chuck 2200 may convexly protrude toward the deposition mask 2050 by a displacement amount of about 0.5 μm to about 2 μm. As a result, the substrate 2010 may be deformed such that the central portion of the substrate 2010 is adjacent to a central portion of the deposition mask 2050. Accordingly, the gap between the substrate 2010 and the deposition mask 2050 may become uniform, and the parallelism between the substrate 2010 and the deposition mask 2050 may be improved.

Then, in S160, the method may include providing the deposition material onto the substrate 2010 through the deposition mask 2050, and accordingly, forming the deposition material layer on the substrate 2010. For example, the deposition source 2150 may evaporate the organic material for forming the light emitting layers on the substrate 2010, and the evaporated organic material may be deposited on the electrode patterns of the substrate 2010 through the pixel openings 2072 of the deposition mask 2050.

After the deposition material layer is formed on the substrate 2010 as described herein, the method may include unloading the substrate 2010 from the substrate chuck 2200. For example, the method may include removing the force applied from the chuck pressurizing portion 2600 to the substrate chuck 2200, and accordingly, the substrate chuck 2200 and the substrate 2010 may be restored to a state before being deformed. The hexapod actuator 2410 may raise the substrate chuck 2200 such that the substrate 2010 is spaced apart from the deposition mask 2050, and the second actuator 2430 may raise the substrate chuck 2200 to a height for unloading the substrate 2010. The finger drivers 2260 may raise the lift fingers 2250 such that the lift fingers 2250 are positioned above the substrate chuck 2200, and may then rotate the lift fingers 2250 such that the ends of the lift fingers 2250 overlap the edge portions of the substrate 2010. The power supply unit 2230 may apply the first reverse voltage and the second reverse voltage to the first electrostatic electrode 2210 and the second electrostatic electrode 2220, respectively, in order to unload the substrate 2010, and the finger drivers 2260 may lower the lift fingers 2250, as illustrated in FIG. 14. The lift fingers 2250 may be lowered through the slots 2202 of the substrate chuck 2200, and the substrate 2010 may be quickly separated from the substrate chuck 2200 by the ends of the lift fingers 2250. In this case, the robot arm 2280 of the transfer robot may be positioned under the substrate chuck 2200. The substrate 2010 separated from the substrate chuck 2200 may be placed on the robot arm 2280 of the transfer robot, and may be carried out from the process chamber 2100 by the transfer robot.

The terms “primarily” and “secondarily” used herein may refer to an order (i.e., first and second). It is to be understood that the term “primarily” is not necessarily limited to meaning “mainly,” “principally,” “higher importance,” or the like in comparison to the term “secondarily” recited herein.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” “may be lifted,” “may be moved,” “may be applied,” and the like include methods, processes, and techniques supportive of such descriptions in accordance with example aspects described herein.

Example aspects supported by the present disclosure should not be construed as being limited to the embodiments set forth herein. Rather, the example embodiments are provided such that this disclosure will be thorough and complete and will fully convey the concepts supported by the present disclosure to those skilled in the art.

While the example aspects supported by the present disclosure have been particularly illustrated and described with reference to embodiments thereof, it will be understood by those of ordinary skill in the art that various changes in form and details may be made therein without departing from the spirit or scope of the concepts supported by the present disclosure as defined by the following claims.

What is claimed is:

1. A deposition apparatus comprising:
a deposition source configured to provide a deposition material onto a substrate;
a substrate chuck configured to support the substrate such that the substrate faces the deposition source;
a mask chuck disposed between the deposition source and the substrate chuck and configured to support a deposition mask such that the deposition mask faces the substrate;
a substrate chuck driver configured to move the substrate chuck such that the substrate is positioned on the deposition mask; and
a chuck pressurizing portion configured to apply pressure to a central portion of the substrate chuck such that the substrate chuck is convexly deformed toward the deposition mask.

2. The deposition apparatus of claim 1, wherein the substrate chuck driver comprises a hexapod actuator configured to provide motion of six degrees of freedom.

3. The deposition apparatus of claim 2, wherein the chuck pressurizing portion comprises a piezo actuator disposed between the hexapod actuator and the substrate chuck and configured to apply the pressure to the central portion of the substrate chuck.

4. The deposition apparatus of claim 1, wherein:
the substrate chuck is an electrostatic chuck configured to hold the substrate using electrostatic force, and
the electrostatic chuck comprises a first electrostatic electrode configured to provide a first electrostatic force associated with holding a central portion of the substrate, and a second electrostatic electrode configured to provide a second electrostatic force associated with holding an edge portion of the substrate.

5. The deposition apparatus of claim 4, further comprising a power supply unit configured to apply a first electrostatic voltage and a second electrostatic voltage to the first electrostatic electrode and the second electrostatic electrode, respectively,
wherein the power supply unit is configured to apply the first electrostatic voltage to the first electrostatic electrode and apply the second electrostatic voltage to the second electrostatic electrode, wherein the second electrostatic voltage is applied after the first electrostatic voltage.

6. The deposition apparatus of claim 1, further comprising a mask chuck driver configured to move the mask chuck in association with adjusting a position of the deposition mask.

7. The deposition apparatus of claim 1, further comprising a plurality of gap sensors configured to measure a gap between the substrate chuck and the mask chuck,
wherein the substrate chuck driver is configured to adjust a gradient of the substrate chuck based on measured values provided by the plurality of gap sensors in association with adjusting parallelism between the substrate and the deposition mask.

8. The deposition apparatus of claim 1, further comprising:
an illumination portion configured to provide light, wherein the substrate and the deposition mask are configured to transmit the light; and
a camera configured to detect the light transmitted through the substrate and the deposition mask.

9. The deposition apparatus of claim 8, wherein the substrate chuck driver is configured to move the substrate chuck in association with aligning the substrate and the deposition mask with each other based on image information acquired by the camera.

10. The deposition apparatus of claim 8, wherein:
the illumination portion comprises an infrared lamp mounted in the substrate chuck, and
the mask chuck has a through hole configured to pass the light transmitted through the substrate and the deposition mask.

11. The deposition apparatus of claim 1, further comprising:
an illumination portion configured to provide light onto the substrate through the deposition mask; and
a camera configured to detect light reflected from the substrate and transmitted through the deposition mask.

12. The deposition apparatus of claim 11, wherein:
the deposition mask comprises a mask frame and a membrane disposed on the mask frame,
the membrane has a mask alignment key, and
the mask frame has a key opening exposing the mask alignment key.

13. The deposition apparatus of claim 1, further comprising a plurality of lift fingers configured to load the substrate onto the substrate chuck and load the deposition mask onto the mask chuck.

14. The deposition apparatus of claim 13, wherein a plurality of slots provided at side portions of the substrate chuck enable raising and lowering movement of the plurality of lift fingers.

15. A method of manufacturing a display panel, the method comprising:
loading a substrate onto a substrate chuck;
loading a deposition mask onto a mask chuck which is disposed facing the substrate chuck;
moving the substrate chuck such that the substrate is positioned on the deposition mask;
applying pressure to a central portion of the substrate chuck such that the substrate chuck is convexly deformed toward the deposition mask; and
forming a deposition material layer on the substrate by providing a deposition material onto the substrate through the deposition mask.

16. The method of claim 15, further comprising:
generating, by the substrate chuck, a first electrostatic force associated with holding a central portion of the substrate, and
generating, by the substrate chuck, a second electrostatic force associated with holding an edge portion of the substrate,
wherein generating the second electrostatic force is after generating the first electrostatic force.

17. The method of claim 15, further comprising:
measuring gaps between the substrate chuck and the mask chuck using a plurality of gap sensors; and
adjusting parallelism between the substrate and the deposition mask based on the measured gaps.

18. The method of claim 15, further comprising:
providing light which transmits through the substrate and the deposition mask;
acquiring image information by detecting the light transmitted through the substrate and the deposition mask; and
aligning the substrate and the deposition mask with each other based on the image information.

19. The method of claim 15, further comprising:
providing light onto the substrate through the deposition mask;
acquiring image information by detecting light reflected from the substrate and transmitted through the deposition mask; and
aligning the substrate and the deposition mask with each other based on the image information.

20. An electronic device comprising a display panel comprising a substrate and a plurality of light-emitting layers formed on the substrate by a deposition apparatus comprising:
a deposition source configured to provide a deposition material onto the substrate;
a substrate chuck configured to support the substrate such that the substrate faces the deposition source;
a mask chuck disposed between the deposition source and the substrate chuck and configured to support a deposition mask such that the deposition mask faces the substrate;
a substrate chuck driver configured to move the substrate chuck such that the substrate is positioned on the deposition mask; and
a chuck pressurizing portion configured to apply pressure to a central portion of the substrate chuck such that the substrate chuck is convexly deformed toward the deposition mask.
